(19) United States
(12) Patent Application Publication
(10) Pub. No.: US 2026/0333984 A1
(43) Pub. Date: Oct. 22, 2026

(54) METHOD OF MANUFACTURING DISPLAY APPARATUS, DISPLAY MODULE, AND DISPLAY APPARATUS

(71) Applicant: SAMSUNG ELECTRONICS CO., LTD., Suwon-si (KR)

(72) Inventors: Jeongyun KIM, Suwon-si (KR); Yeonghyeon SEO, Suwon-si (KR); Byounghoon KANG, Suwon-si (KR); Wonsoon PARK, Suwon-si (KR); Yongho KIM, Suwon-si (KR)

(73) Assignee: SAMSUNG ELECTRONICS CO., LTD., Suwon-si (KR)

(21) Appl. No.: 19/704,811

(22) Filed: Jun. 11, 2026

Related U.S. Application Data
(63) Continuation of application No. PCT/KR2026/000712, filed on Jan. 13, 2026.

(30) Foreign Application Priority Data
Feb. 14, 2025 (KR) 10-2025-0019719

(51) Int. Cl. H10H 29/853; H10H 29/01; H10H 29/49; H10H 29/856

(52) U.S. Cl. CPC H10H 29/853; H10H 29/012; H10H 29/0362; H10H 29/49; H10H 29/856

(57) ABSTRACT

A method of manufacturing a display apparatus includes mounting a plurality of inorganic light-emitting elements that respectively a first electrode, a second electrode, and a semiconductor layer configured to emit light based on a voltage being applied between the first electrode and the second electrode, on a mounting surface of a substrate, such that the first electrode faces the mounting surface, forming a light-transmitting electrode layer, which is configured to electrically connect the second electrode of the plurality of inorganic light-emitting elements, respectively, on one side of the plurality of inorganic light-emitting elements opposite the mounting surface, forming a barrier layer configured to cover the light-transmitting electrode layer by depositing a light-transmitting material on one side of the light-transmitting electrode layer opposite the plurality of inorganic light-emitting elements, and covering the barrier layer by attaching an optical film to one side of the barrier layer opposite the light-transmitting electrode layer.

### CROSS-REFERENCE TO RELATED APPLICATION

This application is a continuation application, under 35 U.S.C. § 111(a), of international application No. PCT/KR2026/000712 filed Jan. 13, 2026, which claims priority under 35 U.S.C. § 119 to Korean Patent Application No. 10-2025-0019719, filed Feb. 14, 2025, the disclosures of which are incorporated herein by reference in their entireties.

### TECHNICAL FIELD

The present disclosure relates to a method of manufacturing a display apparatus, a display module, and a display apparatus.

### BACKGROUND ART

Display apparatuses may be classified into a self-light emitting display in which each pixel emits light by itself and a light-receiving display in which a separate light source is required.

Because a self-light emitting display in which a light-emitting element is provided for each pixel so that each pixel emits light by itself does not require components such as a backlight unit and a liquid crystal layer and may not even require a color filter, the self-light emitting display is structurally simple and thus may have a high degree of design freedom. In addition, the self-light emitting display may realize not only a thin thickness, but also an excellent contrast ratio, brightness and viewing angle.

Among the self-light emitting displays, a micro-LED display may include a plurality of LEDs with a micro-unit size. Compared to an LCD, which require a backlight, the micro-LED display may offer an excellent contrast, response time and energy efficiency.

LEDs may be classified into horizontal LEDs, vertical LEDs, and flip LEDs depending on structures thereof.

In the case of a vertical LED, an electrode connected to a P-type semiconductor and an electrode connected to a N-type semiconductor are arranged in a direction perpendicular to a substrate, so that the LED may be implemented in a relatively small size and may implement high light output compared to the size.

### DISCLOSURE

### Technical Problem

The present disclosure is directed to providing a method of manufacturing a display apparatus, a display module, and a display apparatus that are improved to be capable of preventing moisture, foreign substances, etc. from entering between layers of the display module and protecting the display module.

The present disclosure is directed to providing a method of manufacturing a display apparatus, a display module, and a display apparatus that are improved such that the thickness uniformity of a barrier layer is improved and a deviation between the display modules is reduced.

The present disclosure is directed to providing a method of manufacturing a display apparatus, a display module, and a display apparatus that are improved such that the thickness uniformity of an optical film is improved and a deviation between the display modules is reduced.

The present disclosure is directed to providing a method of manufacturing a display apparatus, a display module, and a display apparatus that are improved to reduce thin film interference caused by light incident toward a transparent electrode layer.

Technical tasks to be achieved in this document are not limited to the technical tasks mentioned above, and other technical tasks not mentioned will be clearly understood by those skilled in the art from the description below.

### Technical Solution

A method of manufacturing a display apparatus according to an embodiment of the present disclosure may include: mounting a plurality of inorganic light-emitting elements that respectively include a first electrode, a second electrode, and a semiconductor layer that is configured to emit light based on a voltage being applied between the first electrode and the second electrode, on a mounting surface of a substrate, such that the first electrode faces the mounting surface; forming a light-transmitting electrode layer, which is configured to electrically connect the second electrode of the plurality of inorganic light-emitting elements, respectively, on one side of the plurality of inorganic light-emitting elements opposite the mounting surface; forming a barrier layer configured to cover the light-transmitting electrode layer by depositing a light-transmitting material on one side of the light-transmitting electrode layer opposite the plurality of inorganic light-emitting elements; and covering the barrier layer by attaching an optical film to one side of the barrier layer opposite the light-transmitting electrode layer.

A display module according to an embodiment of the present disclosure may include: a substrate including circuit lines; a plurality of inorganic light-emitting elements mounted on the substrate; the plurality of inorganic light-emitting elements including a first electrode connected to a circuit line, among the circuit lines, a second electrode opposite the first electrode, and a semiconductor layer configured to emit light based on a voltage being applied between the first electrode and the second electrode; a light-transmitting electrode layer configured to cover the plurality of inorganic light-emitting elements and to be electrically connected to the second electrode of the plurality of inorganic light-emitting elements, respectively; a barrier layer configured to cover the light-transmitting electrode layer by being deposited on one side of the light-transmitting electrode layer opposite the plurality of inorganic light-emitting elements; and an optical film configured to cover the barrier layer by being attached to one side of the barrier layer opposite the light-transmitting electrode layer.

A display apparatus according to an embodiment of the present disclosure may include: a plurality of display modules arranged in a matrix form of M*N. Each of the plurality of display modules may include: a substrate including circuit lines; a light-emitting layer including a plurality of inorganic light-emitting elements including a semiconductor layer configured to emit light based on a voltage being applied between electrodes connected to the circuit lines and an adhesive film configured to mount the plurality of inorganic light-emitting elements on the substrate; a barrier layer configured to cover the light-emitting layer by being deposited on one side of the light-emitting layer opposite the substrate; and an optical film configured to cover the barrier layer by being attached to one side of the barrier layer opposite the light-emitting layer.

### DESCRIPTION OF DRAWINGS

FIG. 1 is a perspective view of a display apparatus according to an embodiment of the present disclosure.

FIG. 2 is an exploded perspective view of the display apparatus according to an embodiment of the present disclosure.

FIG. 3 is an enlarged cross-sectional view illustrating some components of the display apparatus according to an embodiment of the present disclosure.

FIG. 4 is an enlarged cross-sectional view illustrating an optical film included in the display apparatus according to an embodiment of the present disclosure.

FIG. 5 is an enlarged cross-sectional view illustrating the optical film included in the display apparatus according to an embodiment of the present disclosure.

FIG. 6 is a view illustrating mounting and connecting a semiconductor element to a substrate, which is comprised in a method of manufacturing the display apparatus according to an embodiment of the present disclosure.

FIG. 7 is a view illustrating a state after the semiconductor element is mounted and connected to the substrate, which is comprised in the method of manufacturing the display apparatus according to an embodiment of the present disclosure.

FIG. 8 is a view illustrating forming of a light-transmitting electrode layer, which is comprised in the method of manufacturing the display apparatus according to an embodiment of the present disclosure.

FIG. 9 is a view illustrating forming of a barrier layer, which is comprised in the method of manufacturing the display apparatus according to an embodiment of the present disclosure.

FIG. 10 is a view illustrating attaching of the optical film to the barrier layer, which is comprised in the method of manufacturing the display apparatus according to an embodiment of the present disclosure.

FIG. 11 is a view illustrating a method of manufacturing the optical film included in the display apparatus according to an embodiment of the present disclosure.

FIG. 12 is a graph showing a reflectance depending on a wavelength of incident light incident toward the barrier layer and the light-transmitting electrode layer according to a composition of the barrier layer in various embodiments.

FIG. 13 is a graph showing a reflectance depending on a wavelength of incident light incident toward the barrier layer and the light-transmitting electrode layer according to a composition of the barrier layer in various embodiments.

FIG. 14 is an enlarged cross-sectional view illustrating some components of the display apparatus according to an embodiment of the present disclosure.

FIG. 15 is an enlarged cross-sectional view illustrating some components of the display apparatus according to an embodiment of the present disclosure.

### MODE OF THE DISCLOSURE

The embodiments described in this specification and the configurations shown in the drawings are only examples of embodiments of the present disclosure, and various modifications may be made at the time of filing of the present disclosure to replace the embodiments and drawings of the present specification.

Like reference numbers or signs in the various drawings of the present disclosure represent parts or components that perform substantially the same functions.

The terms used in this specification are for the purpose of describing the embodiments and are not intended to restrict and/or to limit the present disclosure. For example, the singular expressions herein may include plural expressions, unless the context clearly dictates otherwise. Also, the terms “comprises” and “has” in this specification are intended to indicate that there are features, numbers, steps, operations, components, parts, or combinations thereof described in the specification, and do not exclude the presence or addition of one or more other features, numbers, steps, operations, components, parts, or combinations thereof.

It will be understood that, although terms including ordinal numbers, such as “first,” “second,” etc., used in this specification may be used to describe various components, these components should not be limited by these terms, and the terms are only used to distinguish one from another component. For example, a first component may be referred to as a second component without departing from the scope of the present disclosure, and similarly, the second component may also be referred to as a first component. The term “and/or” includes any combination of a plurality of related items or any one of a plurality of related items.

The terms “unit,” “module,” “member,” and “block” used in this specification may be implemented as hardware or software, and depending on embodiments, a plurality of “units,” “modules,” “members,” and “blocks” may be implemented as one component, or one “unit,” “module,” “member,” and “block” may include a plurality of components.

Hereinafter, various embodiments of the present disclosure will be described in detail with reference to the accompanying drawings.

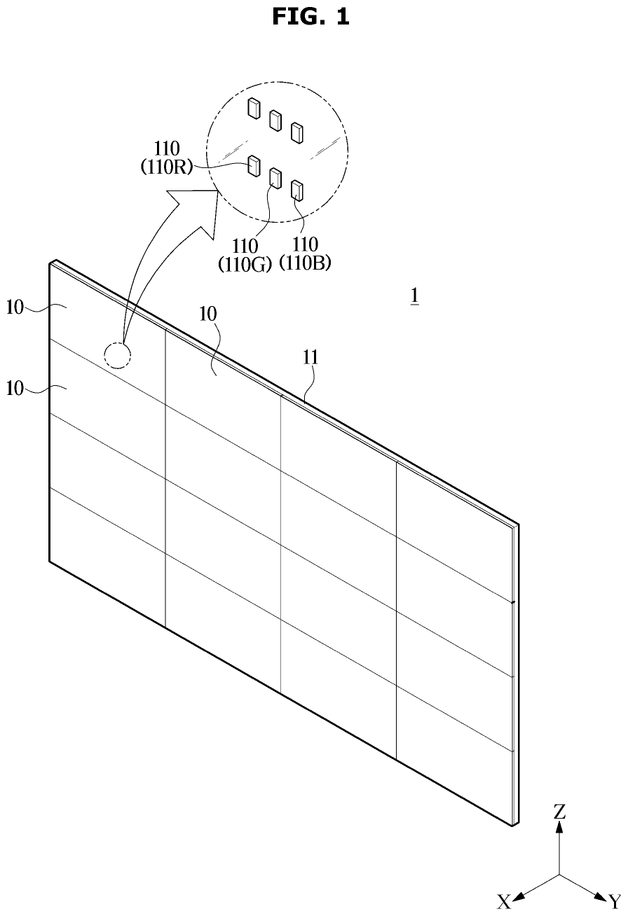

In the description of various embodiments of the present disclosure with reference to FIGS. 1 to 15, the terms “front-rear direction,” “up-down direction,” “left-right direction,” and the like used in the following description are defined with respect to a display apparatus according to various embodiments shown in the drawings, and a shape and position of each component are not limited by these terms. For example, the term “front-rear direction” may refer to a direction parallel to the Z direction with respect to the drawings. For example, the term “up-down direction” may refer to a direction parallel to the Y direction with respect to the drawings. For example, the term “left-right direction” may refer to a direction parallel to the X direction with respect to the drawings.

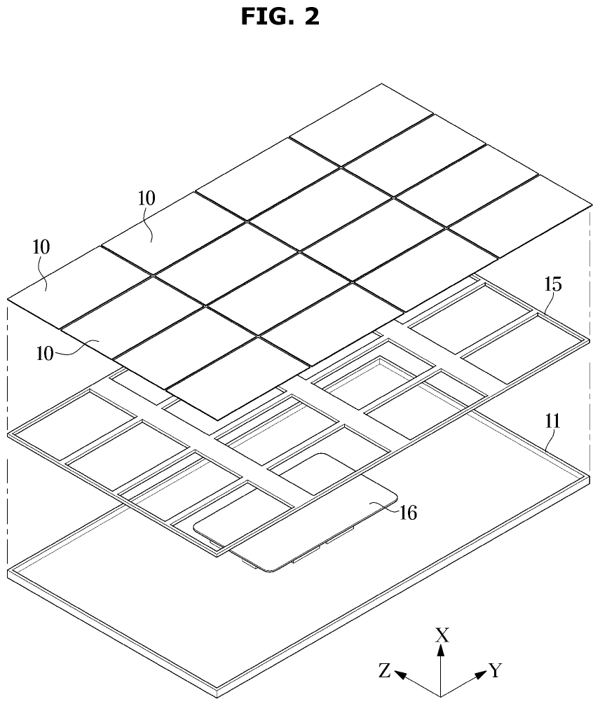

FIG. 1 is a perspective view of a display apparatus according to an embodiment of the present disclosure. FIG. 2 is an exploded perspective view of the display apparatus according to an embodiment of the present disclosure.

Referring to FIGS. 1 and 2, a display apparatus 1 according to various embodiments of the present disclosure is a device capable of processing an image signal received from the outside and visually displaying the processed image.

For example, the display apparatus 1 according to various embodiments of the present disclosure may be implemented in various forms such as a television (TV), a monitor, which is a type of computer output device, a portable multimedia device, a portable communication device, and digital signage. For example, the display apparatus 1 according to various embodiments of the present disclosure may be a large format display (LFD) installed outdoors, such as on a building rooftop and at a bus stop. Herein, the outdoors is not necessarily limited to outdoors, and the display apparatus 1 according to various embodiments of the present disclosure may be installed in any indoor location where many people may enter and exit, such as, for example, a subway station, a shopping mall, a movie theater, a company, and a store. As long as the display apparatus 1 according to various embodiments of the present disclosure is a device that visually displays an image, the type thereof is not limited to that described above.

For example, the display apparatus 1 may be installed in a standing manner on a floor or furniture indoors or outdoors. For example, the display apparatus 1 may be installed on a wall surface or inside a wall of a building or other structure. For example, the display apparatus 1 may be installed on a wall by a wall mount device.

FIGS. 1 and 2 illustrate an example in which the display apparatus 1 is a flat display apparatus having a flat screen, but embodiments are not limited thereto, and the display apparatus 1 according to various embodiments of the present disclosure may include a curved display apparatus or a bendable or flexible display apparatus capable of being changed between a flat state and a curved state. The configuration of the present disclosure described below may be applied to display apparatuses of various shapes regardless of a screen size or ratio of the display apparatus.

The display apparatus 1 may receive content including video signals and audio signals from various content sources, and output video and audio corresponding to the video signals and audio signals. For example, the display apparatus 1 may receive content data via a broadcast receiving antenna or a wired cable, receive content data from a content playback device, or receive content data from a content provision server of a content provider.

The display apparatus 1 may display images corresponding to video data and output sounds corresponding to audio data. For example, the display apparatus 1 may restore a plurality of image frames included in the video data and continuously display the plurality of image frames. In addition, the display apparatus 1 may restore audio signals included in the audio data and continuously output sounds according to the audio signals.

According to an embodiment of the present disclosure, the display apparatus 1 may include a plurality of display modules 10. Each of the plurality of display modules 10 may be configured to output an image. The display apparatus 1 may provide a single large image in which images from the plurality of respective display modules 10 are combined.

The plurality of display modules 10 may be arranged adjacent to each other. The plurality of display modules 10 may be arranged adjacent to each other in an up-down direction or a left-right direction. The plurality of display modules 10 may be arranged in a matrix form of M*N (herein, M and N are natural numbers, and at least one of M and N is a natural number greater than or equal to 2). In this embodiment, the plurality of display modules 10 is provided in 16 units and arranged in a matrix form of 4*4, but the number and arrangement method of the plurality of display modules 10 are not limited thereto.

The display apparatus 1 may include a board assembly 16. Electronic components may be mounted on the board assembly 16, and circuits including the electronic components may be provided on the board assembly 16. For example, the circuits of the board assembly 16 may be formed by printing a conductive material such as copper (Cu) in a circuit line pattern on an electrically insulating substrate.

For example, the board assembly 16 may include a main board configured to control the overall operation of the display apparatus 1, a power supply board configured to supply power to various components of the display apparatus 1, and a source board configured to control operations of light sources (e.g., inorganic light-emitting elements 110) included in the plurality of display modules 10. Circuit boards of the board assembly 16, including the main board, power supply board, and source board, may be arranged independently of each other or merged with each other. When the circuit boards are arranged independently of each other, the circuit boards may be electrically connected to each other to send and receive data, signals, or power.

The display apparatus 1 may include a frame 15 configured to support the plurality of display modules 10, and a rear cover 11 configured to support the rear of the frame 15.

The plurality of display modules 10 may be mounted on the frame 15. The plurality of display modules 10 may be tiled in a matrix form by being mounted on the frame 15. The plurality of display modules 10 may be installed on the frame 15 using various known methods, such as magnetic forces using magnets, mechanical fitting structures, and attachment using adhesives.

The rear cover 11 may be coupled to the rear of the frame 15. The rear cover 11 may cover the rear of the plurality of display modules 10, the frame 15, and the board assembly 16. The rear cover 11 may form a rear appearance of the display apparatus 1.

According to an embodiment, the rear cover 11 may include a metal material. Accordingly, heat generated from the plurality of display modules 10 and board assembly 16, or heat transferred to the frame 15 may be conducted to the rear cover 11, and heat dissipation efficiency of the display apparatus 1 may be improved.

The rear cover 11 may be installed on a floor or on a furniture through a stand, or on a wall through a wall mount device, etc.

By the components of the embodiment described above, the display apparatus 1 may implement a large-area screen by tiling the plurality of display modules 10.

The plurality of display modules 10 may have the same component. The description of any one of the display modules 10 described below may be applied to all of the other display modules 10.

The display module 10 may include a screen configured to display an image. The screen may be provided on one surface of a front side (i.e., front surface) of the display module 10. The display module 10 may display images in front through the screen.

A plurality of pixels may be formed on the screen. An image displayed on the screen may be formed by light emitted by each of the plurality of pixels. For example, an image may be formed on the screen by combining light emitted by the plurality of pixels like a mosaic.

Each of the plurality of pixels may emit light of various brightness and colors. Specifically, each of the plurality of pixels may include sub-pixels, and the sub-pixels may include a red sub-pixel capable of emitting red light, a green sub-pixel capable of emitting green light, and a blue sub-pixel capable of emitting blue light. For example, red light may represent light with a wavelength of about 620 nm (nanometer, one billionth of a meter) to 750 nm, green light may represent light with a wavelength of about 495 nm to 570 nm, and blue light may represent light with a wavelength of about 450 nm to 495 nm.

Each of the plurality of pixels may emit light of various brightness and colors by combining light emitted from the red sub-pixel, green sub-pixel, and blue sub-pixel, respectively.

Sub-pixels may be arranged along a left-right direction Y. Sub-pixels may be arranged along an up-down direction Z. Unlike these, sub-pixels may not be arranged in a row with each other.

According to an embodiment, the display module 10 may be a self-light emitting display type in which a light-emitting element is arranged for each pixel so that each pixel may emit light by itself. In this embodiment, unlike a liquid crystal display type, the display module 10 does not need to have components such as a backlight unit and a liquid crystal layer and thus may implement a thin thickness, and has a relatively simple structure and thus may allow various design changes.

According to an embodiment, the display module 10 may include a plurality of inorganic light-emitting elements 110. Each of the plurality of inorganic light-emitting elements 110 may form a sub-pixel. The plurality of inorganic light-emitting elements 110 may include a red inorganic light-emitting element 110R, a green inorganic light-emitting element 110G, and a blue inorganic light-emitting element 110B. Each of the plurality of inorganic light-emitting elements 110 may be a micro LED having a short side length of about 100 μm, about tens μm, or about several μm.

The red inorganic light-emitting element 110R, the green inorganic light-emitting element 110G, and the blue inorganic light-emitting element 110B may be arranged in a row at a predetermined interval as shown in FIG. 1. However, the light-emitting elements are not limited thereto and may be arranged in other shapes, such as a triangular shape.

Additionally, the present disclosure exemplifies, but is not limited to, a case where one pixel is composed of three sub-pixels corresponding to R, G, and B, respectively. One pixel may be composed of two sub-pixels of R and G or G and B or B and R, or three sub-pixels of R, B, and W, or four sub-pixels of R, G, B, and W (white), or more sub-pixels.

The components of the display apparatus 1 described above with reference to FIGS. 1 and 2 are merely examples of components that may be included in the display apparatus 1 according to an embodiment of the present disclosure, and the present disclosure is not limited thereto. The display apparatus 1 according to various embodiments of the present disclosure may include various components for performing various functions of the display apparatus 1.

Unlike the embodiment described above, only the single display module 10 may be applied to the display apparatus 1. The display module 10 may be installed and applied as a single unit to various electronic products or electrical products requiring various displays, such as TVs, wearable devices, portable devices, and PC monitors.

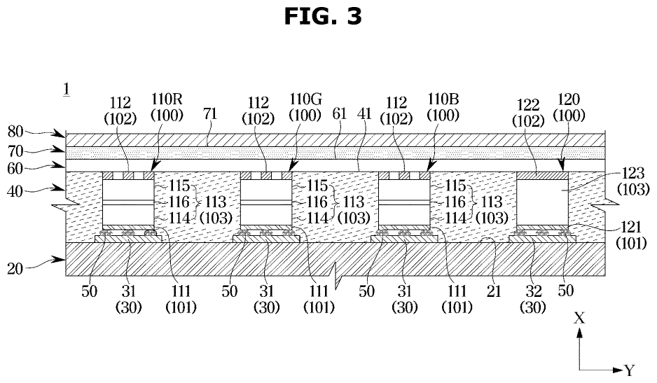

FIG. 3 is an enlarged cross-sectional view illustrating some components of the display apparatus according to an embodiment of the present disclosure.

Referring to FIG. 3, the display module 10 included in the display apparatus 1 according to an embodiment of the present disclosure may include a substrate 20. The substrate 20 may be configured to support other components of the display module 10. For example, various semiconductor elements 100, such as the aforementioned inorganic light-emitting elements 110, may be mounted on a front surface 21 of the substrate 20.

As an example, the substrate 20 may have a substantially flat plate shape.

As an example, the substrate 20 may include a transparent glass material mainly composed of silicon dioxide (SiO₂). However, the material of the substrate 20 is not limited thereto, and in various embodiments, the substrate 20 may include materials such as polyimide, PET, and FR4.

The substrate 20 may include circuit lines. The substrate 20 may include a thin film transistor (TFT) layer and various wirings (e.g., data lines, gate lines, power lines, etc.). For example, the thin film transistor layer of the substrate 20 may include transistor circuits for individually controlling the semiconductor elements 100, such as the plurality of inorganic light-emitting elements 110. Various wirings of the substrate 20 may transmit various electrical signals (e.g., data signals, gate signals, power signals) to the light-emitting element 14.

The display module 10 may include a substrate electrode 30 provided on the substrate 20. For example, the substrate electrode 30 may be provided on the front surface 21 of the substrate 20 on which the semiconductor element 100 is mounted. The substrate electrode 30 may be connected to the circuit line of the substrate 20. The substrate electrode 30 may be provided in plurality.

The substrate electrodes 30 may include at least one positive pole 31 and at least one negative pole 32. The positive pole 31 and the negative pole 32 may be arranged spaced apart from each other on the substrate 20.

The positive pole 31 may be an electrode provided to transmit a driving current supplied from the thin film transistor layer of the substrate 20 to the plurality of inorganic light-emitting elements 110. The positive pole 31 may be electrically connected to a first electrode 111 included in each of the plurality of inorganic light-emitting elements 110. For example, the positive pole 31 may be provided in plurality and electrically connected to the first electrode 111 of the red inorganic light-emitting element 110R, the first electrode 111 of the green inorganic light-emitting element 110G, and the first electrode 111 of the blue inorganic light-emitting element 110B, respectively. The positive pole 31 may be referred to as an anode.

The negative pole 32 may be an electrode provided to allow driving current to flow from a connector element 120, which will be described later. The negative pole 32 may be provided to connect the connector element 120, which will be described later, to the substrate 20. The negative pole 32 may be electrically connected to a first electrode 121 included in the connector element 120, which will be described later. The negative pole 32 may be referred to as a cathode.

According to an embodiment, the one negative pole 32 may be electrically connected as a common electrode to a plurality of the positive poles (e.g., the positive poles 31 connected to the first electrodes 111 of the red inorganic light-emitting element 110R, the green inorganic light-emitting element 110G, and the blue inorganic light-emitting element 110B, respectively).

In the above, an embodiment has been described in which among the substrate electrodes 30, the electrode 31 connected to the inorganic light-emitting element 110 is a positive pole and the electrode 32 connected to the connector element 120 is a negative pole, but the present disclosure is not limited thereto, and in various embodiments, among the substrate electrodes 30, the electrode 31 connected to the inorganic light-emitting element 110 may be a negative pole and the electrode 32 connected to the connector element 120 may be a positive pole.

However, for convenience of explanation, an embodiment will be described below on the assumption that the electrode 31 connected to the inorganic light-emitting element 110 is a positive pole and the electrode 32 connected to the connector element 120 is a negative pole.

According to an embodiment, the display module 10 may include the semiconductor element 100. The semiconductor element 100 may be mounted on the substrate 20. The semiconductor element 100 may be mounted on the front surface 21 of the substrate 20. The semiconductor element 100 may be connected to the substrate electrode 30. The semiconductor element 100 may be electrically connected to the circuit line of the substrate 20 via the substrate electrode 30.

The semiconductor element 100 may be provided in multiples. For example, the semiconductor element 100 may include the plurality of the aforementioned inorganic light-emitting elements 110. For example, the semiconductor element 100 may include the connector element 120 electrically connected to the plurality of inorganic light-emitting elements 110. As an example, the one connector element 120 may be electrically connected to the plurality of inorganic light-emitting elements 110.

Each of the plurality of inorganic light-emitting elements 110 may include the first electrode 111 electrically connected to the substrate 20, a second electrode 112 opposite to the first electrode 111, and a semiconductor layer 113 through which current flows based on a predetermined voltage being applied between the first electrode 111 and the second electrode 112. According to an embodiment, the inorganic light-emitting element 110 may be configured as a vertical LED type in which the first electrode 111 and the second electrode 112 are arranged in a direction perpendicular to the substrate 20. As an example, the first electrode 111 and the second electrode 112 of the inorganic light-emitting element 110 may be arranged in a front-rear direction X parallel to a direction in which light is emitted. As an example, the second electrode 112 of the inorganic light-emitting element 110 may be disposed in front further than the first electrode 111.

The first electrode 111 may be disposed on one surface of the semiconductor layer 113 adjacent to the substrate 20. The first electrode 111 may be disposed on a back surface of the semiconductor layer 113.

The first electrode 111 of the inorganic light-emitting element 110 may be connected to a circuit line of the substrate 20. The first electrode 111 of the inorganic light-emitting element 110 may be connected to the substrate electrode 30 provided on the substrate 20. The first electrode 111 may be connected to the positive pole 31 provided on the substrate 20. As an example, a conductive layer 50 including a material having high electrical conductivity may be formed between the first electrode 111 and the positive pole 31, and the first electrode 111 and the positive pole 31 may be connected to each other by the conductive layer 50. As an example, the conductive layer 50 may include a plurality of conductive balls dispersed within an adhesive film 40, which will be described later. The plurality of conductive balls, which is conductive particles surrounded by thin insulating films, may be configured to electrically connect conductors to each other along a pressing direction by breaking the insulating films by pressure. In a process of mounting the inorganic light-emitting element 110 on the substrate 20, the insulating films of the conductive balls located between the first electrode 111 of the inorganic light-emitting element 110 and the substrate electrode 30 (e.g., the positive pole 31) may be broken and the first electrode 111 and the substrate electrode 30 may be connected. The conductive ball of the conductive layer 50 may include various metal materials such as Au, Ni, and Pd as a conductive particle.

The first electrode 111 may be a P-type electrode.

The first electrode 111 of the inorganic light-emitting element 110 may also be referred to by a term such as ‘first light-emitting element electrode’.

The second electrode 112 of the inorganic light-emitting element 110 may be disposed to face the first electrode 111. The second electrode 112 may be disposed on the other surface of the semiconductor layer 113 opposite to the substrate 20. The second electrode 112 may be disposed on a front surface of the semiconductor layer 113.

The second electrode 112 may be an N-type electrode.

According to an embodiment, the second electrode 112 may be provided in plurality. For example, the second electrodes 112 may be provided in plurality and disposed at edges and a central portion of the inorganic light-emitting element 110, respectively.

A size of the second electrode 112 may be smaller than a size of the first electrode 111. However, the size of the second electrode 112 is not limited thereto, and in various embodiments, may be larger than the size of the first electrode 111 or may be the same as the size of the first electrode 111.

The second electrode 112 of the inorganic light-emitting element 110 may also be referred to by a term such as ‘second light-emitting element electrode’.

The semiconductor layer 113 of the inorganic light-emitting element 110 may be configured to allow current to flow based on the predetermined voltage being applied between the first electrode 111 and the second electrode 112. The semiconductor layer 113 of the inorganic light-emitting element 110 may be configured to allow current to flow based on the predetermined voltage being applied between the back surface on which the first electrode 111 is disposed and the front surface on which the second electrode 112 is disposed.

According to an embodiment, the semiconductor layer 113 of the inorganic light-emitting element 110 may include a first semiconductor layer 114, a second semiconductor layer 115, and an active layer 116 disposed between the first semiconductor layer 114 and the second semiconductor layer 115. The first semiconductor layer 114, the active layer 116, and the second semiconductor layer 115 may be arranged in the direction perpendicular to the substrate 20. For example, the first semiconductor layer 114, the active layer 116, and the second semiconductor layer 115 may be arranged in the front-rear direction X, which is a direction in which light is emitted. For example, the active layer 116 may be disposed in front of the first semiconductor layer 114, and the second semiconductor layer 115 may be disposed in front of the active layer 116.

The first semiconductor layer 114 may be a P-type semiconductor layer. For example, the first semiconductor layer 114 may be a P-GaN layer doped with a P-type material.

The first semiconductor layer 114 may be in contact with the first electrode 111. The first semiconductor layer 114 may be electrically connected to the substrate 20 via the first electrode 111. The first semiconductor layer 114 may be electrically connected to the substrate electrode 30 (e.g., the positive pole 31) of the substrate 20 via the first electrode 111. For example, a driving current from the positive pole 31 may flow to the first semiconductor layer 114 via the first electrode 111 of the inorganic light-emitting element 110.

The second semiconductor layer 115 may be a N-type semiconductor layer. For example, the second semiconductor layer 115 may be a N-GaN layer doped with a N-type material.

The second semiconductor layer 115 may be in contact with the second electrode 112. The second semiconductor layer 115 may be electrically connected to a light-transmitting electrode layer 60, which will be described later, via the second electrode 112.

The active layer 116 may be disposed between the first semiconductor layer 114 and the second semiconductor layer 115 and configured to emit light by combining electrons and holes when the predetermined voltage is applied between the first electrode 111 and the second electrode 112 of the semiconductor layer 113. For example, the active layer 116 may be configured as a quantum well (such as a multiple-quantum-well (MQW) or a single-quantum-well (SQW)).

The semiconductor layer 113 of the inorganic light-emitting element 110 may be referred to by a term such as ‘light-emitting element semiconductor layer’. The first semiconductor layer 114 of the inorganic light-emitting element 110 may be referred to by a term such as ‘first light-emitting element semiconductor layer’. The second semiconductor layer 115 of the inorganic light-emitting element 110 may be referred to by a term such as ‘second light-emitting element semiconductor layer’. The active layer 116 of the inorganic light-emitting element 110 may be referred to by a term such as ‘light-emitting element active layer’.

In the above description of the configurations of the inorganic light-emitting element 110, an embodiment in which the first electrode 111 is a P-type electrode and the second electrode 112 is an N-type electrode has been described, but the present disclosure is not limited thereto, and in various embodiments, the first electrode 111 may be an N-type electrode and the second electrode 112 may be a P-type electrode. Additionally, in the above description of the configurations of the inorganic light-emitting element 110, an embodiment in which the first semiconductor layer 114 is a P-type semiconductor and the second semiconductor layer 115 is an N-type semiconductor has been described, but the present disclosure is not limited thereto, and in various embodiments, the first semiconductor layer 114 may be an N-type semiconductor and the second semiconductor layer 115 may be a P-type semiconductor.

However, for convenience of explanation, an embodiment will be described below on the assumption that the first electrode 111 is a P-type electrode, the second electrode 112 is an N-type electrode, the first semiconductor layer 114 is a P-type semiconductor, and the second semiconductor layer 115 is an N-type semiconductor.

According to an embodiment of the present disclosure, the display module 10 may include the connector element 120 mounted on the substrate 20 as a type of the semiconductor element 100. The connector element 120 may be mounted on the front surface 21 of the substrate 20. The connector element 120 may be electrically connected to the substrate 20. The connector element 120 may be electrically connected to the plurality of inorganic light-emitting elements 110.

The connector element 120 may include the first electrode 121 electrically connected to the substrate 20, a second electrode 122 opposite to the first electrode 121, and a semiconductor layer 123 through which current flows based on a predetermined voltage being applied between the first electrode 121 and the second electrode 122. According to an embodiment, the first electrode 121 and the second electrode 122 of the connector element 120 are arranged in the direction perpendicular to the substrate 20. As an example, the first electrode 121 and the second electrode 122 of the connector element 120 may be arranged in the front-rear direction X parallel to a direction in which light is emitted. As an example, the second electrode 122 of the connector element 120 may be disposed in front further than the first electrode 121.

The first electrode 121 of the connector element 120 may be disposed on one surface of the semiconductor layer 123 adjacent to the substrate 20. The first electrode 121 may be disposed on a back surface of the semiconductor layer 123. The semiconductor layer 123 may be electrically connected to the substrate 20 via the first electrode 121.

The first electrode 121 of the semiconductor layer 123 may be connected to a circuit line of the substrate 20. The first electrode 121 of the semiconductor layer 123 may be connected to the substrate electrode 30 provided on the substrate 20. The first electrode 121 may be connected to the negative pole 32 provided on the substrate 20. As an example, the conductive layer 50 (e.g., including the plurality of conductive balls) may be formed between the first electrode 121 and the negative pole 32, and the first electrode 121 and the negative pole 32 may be connected to each other by the conductive layer 50.

The first electrode 121 of the connector element 120 may also be referred to by a term such as ‘first connector element electrode’.

The second electrode 122 of the connector element 120 may be disposed to face the first electrode 121. The second electrode 122 may be disposed on the other surface of the semiconductor layer 123 opposite to the substrate 20. The second electrode 122 may be disposed on a front surface of the semiconductor layer 123. The semiconductor layer 123 may be electrically connected to the light-transmitting electrode layer 60, which will be described later, via the second electrode 122.

The second electrode 122 of the connector element 120 may also be referred to by a term such as ‘second connector element electrode’.

The semiconductor layer 123 of the connector element 120 may be configured to allow current to flow based on the predetermined voltage being applied between the first electrode 121 and the second electrode 122. The semiconductor layer 123 may be configured to allow current to flow based on the predetermined voltage being applied between the back surface on which the first electrode 121 is disposed and the front surface on which the second electrode 122 is disposed.

According to an embodiment, the display module 10 may include the adhesive film 40. The adhesive film 40 may be configured to fix the semiconductor element 100 to the substrate 20. For example, the adhesive film 40 may include an anisotropic conductive film (ACF). For example, the adhesive film 40 may include an anisotropic conductive film (black ACF) including a black colored polymer resin. For example, the adhesive film 40 may include a non-conductive film (NCF). For example, the adhesive film 40 may include a non-conductive film (black NCF) including a black colored polymer resin.

According to an embodiment, the adhesive film 40 may be configured to allow electrical connection in the direction perpendicular to the substrate 20 (e.g., the front-rear direction X) but to be insulating in a direction parallel to the substrate 20 (e.g., a direction parallel to a Y-Z plane). For example, the adhesive film 40 may be configured to have the aforementioned conductive layer 50 (e.g., conductive ball) as a conductive medium, and may have various other configurations as conductive mediums.

According to an embodiment, the semiconductor elements 100, such as the plurality of inorganic light-emitting elements 110 and the connector element 120, and the adhesive film 40 may have the same or nearly similar thicknesses in the front-rear direction X. That is, in the display module 10, a plurality of the semiconductor elements 100 and the adhesive film 40 may form one layer, and the layer including the plurality of semiconductor elements 100 and the adhesive film 40 may be referred to as a ‘light-emitting layer’. The light-emitting layer may cover the mounting surface (e.g., the front surface) 21 of the substrate 20. The light-emitting layer may cover almost the entire mounting surface 21 of the substrate 20. The light-emitting layer may be disposed in front further than the substrate 20.

According to an embodiment, the adhesive film 40 may include a thermosetting resin material.

According to an embodiment, the display module 10 may include the light-transmitting electrode layer 60. The light-transmitting electrode layer 60 may be configured to allow light to transmit. The light-transmitting electrode layer 60 may be configured to have electrical conductivity such that current flows therethrough.

The light-emitting electrode layer 60 may be disposed in front further than the substrate 20. The light-transmitting electrode layer 60 may be disposed to face the substrate 20. The light-transmitting electrode layer 60 may be disposed parallel to the substrate 20. As an example, the light-transmitting electrode layer 60 may have a plate shape substantially parallel to the substrate 20.

The light-transmitting electrode layer 60 may cover the semiconductor elements 100, such as the inorganic light-emitting elements 110 and the connector element 120. The light-transmitting electrode layer 60 may be disposed on one side of the semiconductor element 100 opposite to the substrate 20. The light-transmitting electrode layer 60 may be disposed in front further than the semiconductor element 100.

The light-transmitting electrode layer 60 may cover the adhesive film 40. The light-transmitting electrode layer 60 may be disposed on one side of the adhesive film 40 opposite to the substrate 20. The light-transmitting electrode layer 60 may be disposed in front further than the adhesive film 40.

In other words, the light-transmitting electrode layer 60 may cover the light-emitting layer. The light-transmitting electrode layer 60 may be disposed on one side of the light-emitting layer opposite to the substrate 20. The light-transmitting electrode layer 60 may be disposed in front further than the light-emitting layer.

The light-transmitting electrode layer 60 may be electrically connected to the plurality of semiconductor elements 100. The light-transmitting electrode layer 60 may be electrically connected to the second electrode of each of the plurality of semiconductor elements 100. For example, the light-transmitting electrode layer 60 may be electrically connected to the second electrode 112 of the inorganic light-emitting element 110. For example, the light-transmitting electrode layer 60 may be electrically connected to the second electrode 122 of the connector element 120. By the light-transmitting electrode layer 60, the second electrode 112 of each of the plurality of inorganic light-emitting elements 110 and the second electrode 122 of the connector element 120 may be electrically connected.

As an example, the light-transmitting electrode layer 60 may include indium tin oxide (ITO), indium zinc oxide (IZO), nano wire paste, etc.

According to an embodiment, the light-transmitting electrode layer 60 may be formed through a deposition process. The light-transmitting electrode layer 60 may be formed by being deposited on one side (e.g., a front side) of the semiconductor element 100 opposite to the substrate 20. The light-transmitting electrode layer 60 may be formed by being deposited on one side (e.g., a front side) of the plurality of inorganic light-emitting elements 110 opposite to the substrate 20. The light-transmitting electrode layer 60 may be formed by being deposited on one side (e.g., a front side) of the connector element 120 opposite to the substrate 20. The light-transmitting electrode layer 60 may be formed by being deposited on one side (e.g., a front side) of the adhesive film 40 opposite to the substrate 20. The light-transmitting electrode layer 60 may be formed by being deposited on one side (e.g., a front side) of the light-emitting layer opposite to the substrate 20. The light-transmitting electrode layer 60 may be formed by being deposited on a front surface 41 of the light-emitting layer.

The light-transmitting electrode layer 60 may be formed by various methods, such as physical vapor deposition (PVD), chemical vapor deposition (CVD), plasma enhanced CVD (PECVD), low pressure CVD (LPCVD), sputtering, and atomic layer deposition (ALD).

According to an embodiment, the light-transmitting electrode layer 60 may be formed by being applied to one side (e.g., the front side) of the semiconductor element 100 opposite to the substrate 20. The light-transmitting electrode layer 60 may be formed by being applied to one side (e.g., the front side) of the plurality of inorganic light-emitting elements 110 opposite to the substrate 20. The light-transmitting electrode layer 60 may be formed by being applied to one side (e.g., the front side) of the connector element 120 opposite to the substrate 20. The light-transmitting electrode layer 60 may be formed by being applied to one side (e.g., the front side) of the adhesive film 40 opposite to the substrate 20. The light-transmitting electrode layer 60 may be formed by being applied to one side (e.g., a front side) of the light-emitting layer opposite to the substrate 20. The light-transmitting electrode layer 60 may be formed by being applied to the front surface 41 of the light-emitting layer.

As such, the first electrode of the semiconductor element 100 (e.g., the first electrode 111 of the inorganic light-emitting element 110 and the first electrode 121 of the connector element 120) may be connected to the substrate 20 via the substrate electrode 30, the second electrode of the semiconductor element 100 (e.g., the second electrode 112 of the inorganic light-emitting element 110 and the second electrode 122 of the connector element 120) may be connected to the light-transmitting electrode layer 60, and through the control of the substrate 20 and the light-transmitting electrode layer 60, voltage may be applied to each of the semiconductor elements 100 and current may flow through each of the semiconductor elements 100.

According to an embodiment, the display module 10 may include a barrier layer 70. The barrier layer 70 may cover the light-transmitting electrode layer 60. The barrier layer 70 may be disposed on one side of the light-transmitting electrode layer 60 opposite to the semiconductor element 100 or the adhesive film 40. The barrier layer 70 may be disposed on one side of the light-transmitting electrode layer 60 opposite to the light-emitting layer. The barrier layer 70 may be disposed on a front surface 61 of the light-transmitting electrode layer 60. For example, the barrier layer 70 may be in contact with the front surface 61 of the light-transmitting electrode layer 60. For example, the barrier layer 70 may be coupled to the front surface 61 of the light-transmitting electrode layer 60.

The barrier layer 70 may be configured to seal the light-transmitting electrode layer 60. The barrier layer 70 may be configured to seal the light-transmitting electrode layer 60 from the outside on an optical film 80 side, which will be described later. For example, the barrier layer 70 may be configured to seal the front surface 61 of the light-transmitting electrode layer 60.

The barrier layer 70 may be configured to seal the semiconductor elements 100, such as the plurality of inorganic light-emitting elements 110 and the connector element 120. The barrier layer 70 may be configured to seal the semiconductor elements 100, such as the plurality of inorganic light-emitting elements 110 and the connector element 120, from the outside on the optical film 80 side, which will be described later. For example, the barrier layer 70 may be configured to seal the semiconductor elements 100, such as the plurality of inorganic light-emitting elements 110 and the connector element 120, from the front.

The barrier layer 70 may be configured to seal the adhesive film 40. The barrier layer 70 may be configured to seal the adhesive film 40 from the outside on the optical film 80 side, which will be described later. For example, the barrier layer 70 may be configured to seal the adhesive film 40 from the front.

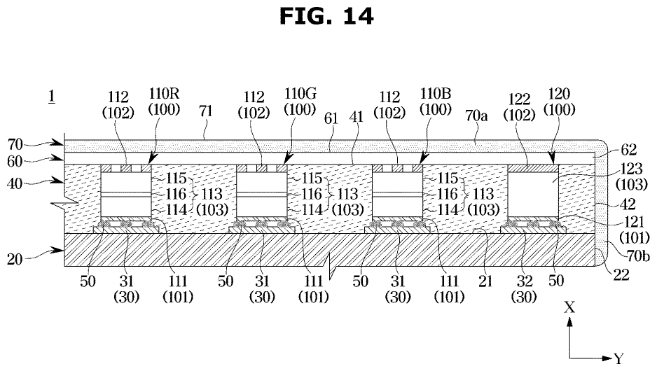

An area covered and sealed by the barrier layer 70 is not limited thereto, and in various embodiments, the barrier layer 70 may be configured to seal side surfaces of the light-transmitting electrode layer 60, the light-emitting layer, etc. in an edge direction (see FIG. 14, etc.).

Accordingly, the barrier layer 70 may protect components such as the light-transmitting electrode layer 60, the semiconductor element 100, the adhesive film 40, and the substrate 20 from external impact, moisture, foreign substances, etc. In particular, the barrier layer 70 may prevent moisture, foreign substances, etc. from penetrating between the respective layers of the display module 10, such as the light-transmitting electrode layer 60, the light-emitting layer, And the Substrate.

The barrier layer 70 may include a light-transmitting material. The barrier layer 70 may be configured to allow light to transmit. Light emitted from the plurality of inorganic light-emitting elements 110 may transmit the light-transmitting electrode layer 60 and the barrier layer 70 and proceed forward. External light incident from the front of the display module 10 may transmit the barrier layer 70 and incident on the light-transmitting electrode layer 60.

Because the light-transmitting electrode layer 60 has a thin thickness despite having high transmittance, the light-transmitting electrode layer 60 may cause a thin film interference phenomenon and strongly reflect light of a specific wavelength. Therefore, external light incident on the light-transmitting electrode layer 60 may be strongly reflected at a specific wavelength, which may lead to a problem in which blackness of the display module 10 is significantly reduced.

In order to prevent this, the barrier layer 70 may be configured such that light that transmits the barrier layer 70 and is incident on the light-transmitting electrode layer 60 is reflected at a reflectivity less than a predetermined reflectivity by the light-transmitting electrode layer 60. The barrier layer 70 may include a material having an appropriate reflectivity or refractive index to reduce a degree to which external light incident from the front is reflected by the light-transmitting electrode layer 60.

It may be appropriate for the barrier layer 70 to have a refractive index of about 1.3 or more and 1.4 or less, but the refractive index of the barrier layer 70 may be variously determined in consideration of refractive indices of the optical film 80 and the light-transmitting electrode layer 60, which will be described later.

For example, the barrier layer 70 may include various light-transmitting materials such as silicon dioxide (SiO₂), silicon nitride (SiNx), magnesium fluoride (MgF₂), aluminum oxide (Al₂O₃), titanium dioxide (TiO₂), and zirconium dioxide (ZrO₂). The barrier layer 70 may include at least one of the above light-transmitting materials.

As an example of methods of forming the barrier layer 70, there is a method using a roll-to-roll process. For example, the barrier layer 70 may be included as a part of an optical film disposed on a front surface of the display module 10, and may be formed by the roll-to-roll process of manufacturing the optical film. However, when the barrier layer 70 is formed by this method, the thickness uniformity of the barrier layer 70 may be reduced, and a deviation may occur between the plurality of display modules 10.

In order to solve this problem, according to an embodiment of the present disclosure, the barrier layer 70 may be formed through the deposition process. The barrier layer 70 may be formed by being deposited on one side (e.g., a front side) of the light-transmitting electrode layer 60 opposite to the semiconductor element 100. The barrier layer 70 may be formed by being deposited on one side (e.g., the front side) of the light-transmitting electrode layer 60 opposite to the plurality of inorganic light-emitting elements 110. The barrier layer 70 may be formed by being deposited on one side (e.g., the front side) of the light-transmitting electrode layer 60 opposite to the connector element 120. The barrier layer 70 may be formed by being deposited on one side (e.g., the front side) of the light-transmitting electrode layer 60 opposite to the adhesive film 40. The barrier layer 70 may be formed by being deposited on one side (e.g., the front side) of the light-transmitting electrode layer 60 opposite to the light-emitting layer. The barrier layer 70 may be formed by being deposited on the front surface 61 of the light-transmitting electrode layer 60.

The barrier layer 70 may be formed by various methods, such as physical vapor deposition (PVD), chemical vapor deposition (CVD), plasma enhanced CVD (PECVD), low pressure CVD (LPCVD), sputtering, and atomic layer deposition (ALD).

For example, the barrier layer 70 may be formed by depositing the light-transmitting material on the light-transmitting electrode layer 60. The barrier layer 70 may be formed to cover the light-transmitting electrode layer 60 as the light-transmitting material is deposited on the light-transmitting electrode layer 60. For example, the barrier layer 70 may be formed by depositing the light-transmitting material such as silicon dioxide (SiO₂) on the light-transmitting electrode layer 60.

As such, as the barrier layer 70 is formed through deposition, the thickness uniformity of the barrier layer 70 may be improved. In addition, the thickness deviation of the barrier layer 70 between the plurality of display modules 10 may be reduced. Accordingly, the performance of the barrier layer 70 to prevent penetration of moisture and foreign substances may be improved. Additionally, the blackness or color deviation between the display modules 10 may be improved, and the visibility of a seam formed between the display modules 10 may be improved. Additionally, the mura phenomenon in the display module 10 may be reduced, and the picture quality may be improved. Additionally, as the thickness uniformity of the barrier layer 70 is improved and the deviation between the display modules 10 is reduced, the ease of manufacturing and manufacturing yield may be improved, and the manufacturing cost may be reduced.

According to an embodiment, the display module 10 may include the optical film 80. The optical film 80 may form the front surface of the display module 10. The optical film 80 may improve the optical properties of light emitted from the front surface of the display module 10, and may protect other components of the display module 10, such as the barrier layer 70, from external impact, static electricity, moisture, or foreign substances.

The optical film 80 may cover the barrier layer 70. For example, the optical film 80 may cover one side of the barrier layer 70 opposite to the light-transmitting electrode layer 60. For example, the optical film 80 may cover a front surface 71 of the barrier layer 70.

The optical film 80 may be attached to the barrier layer 70. The optical film 80 may be attached to, for example, one side of the barrier layer 70 opposite to the light-transmitting electrode layer 60. For example, the optical film 80 may be attached to the front surface 71 of the barrier layer 70.

The optical film 80 may be configured to allow light to transmit. The optical film 80 may include a light-transmitting material.

The configurations of the display apparatus 1 according to the embodiment described above with reference to FIG. 3 are only one example, and the display apparatus 1 may include various configurations in various embodiments of the present disclosure.

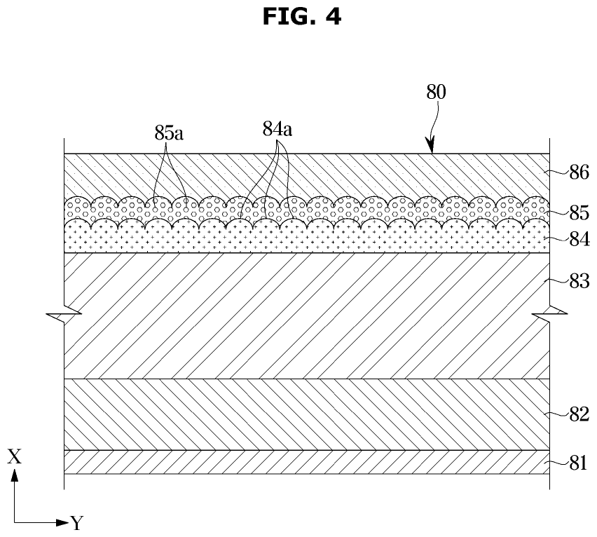

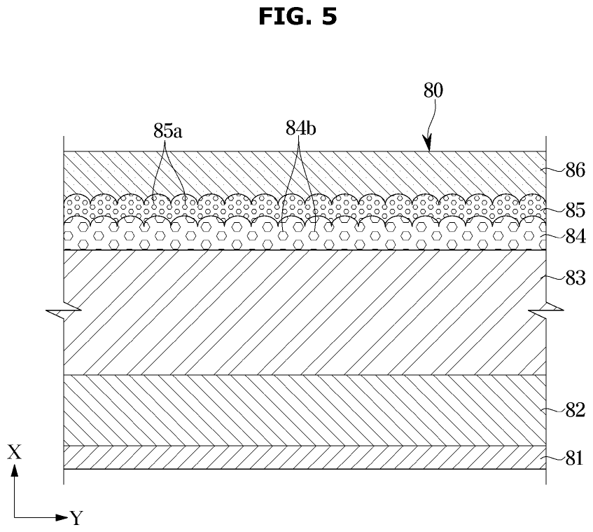

FIG. 4 is an enlarged cross-sectional view illustrating an optical film included in the display apparatus according to an embodiment of the present disclosure. FIG. 5 is an enlarged cross-sectional view illustrating the optical film included in the display apparatus according to an embodiment of the present disclosure.

Referring to FIGS. 4 and 5, the optical film 80 included in the display module 10 of the display apparatus 1 according to an embodiment of the present disclosure may include a film base layer 83, an anti-glare layer 84 for improving optical properties, and a low-reflection layer 85.

The film base layer 83 may be configured to support other layers of the optical film 80. The film base layer 83 may function as a base for other components.

The film base layer 83 may be provided to allow light to transmit. For example, the film base layer 83 may include a light-transmitting polyester material. For example, the film base layer 83 may include an optical PET material.

According to an embodiment, the film base layer 83 may have a thin film shape. As an example, the film base layer 83 may have a flat and thin film shape on both front and back surfaces.

The anti-glare layer 84 may be disposed on one side of the film base layer 83. The anti-glare layer 84 may be supported by the film base layer 83. The anti-glare layer 84 may be disposed on one side of the film base layer 83 opposite to the barrier layer 70. The anti-glare layer 84 may be disposed on one side of the film base layer 83 opposite to a light-transmitting adhesive layer 82, which will be described later. The anti-glare layer 84 may be disposed on the front surface of the film base layer 83.

As an example, the anti-glare layer 84 may have a thin film shape.

The anti-glare layer 84 may be configured to reduce a glare phenomenon by preventing external light from being reflected and strongly shining on the screen of the display module 10. In this end, for example, the anti-glare layer 84 may be configured to scatter light.

As an example of a method for forming the anti-glare layer 84 scattering light, there may be a method of forming a film having an anti-glare function by dispersing a plurality of glass beads 84b, as in the embodiment illustrated in FIG. 5. For example, each of the glass beads 84b may have a low refractive index and a hollow bead shape. However, in this case, because the glass beads 84b may have non-uniform sizes and a degree of dispersion may affect the uniformity, thickness uniformity of the optical film 80 may be reduced and a deviation of the anti-glare layer 84 between the display modules 10 may occur.

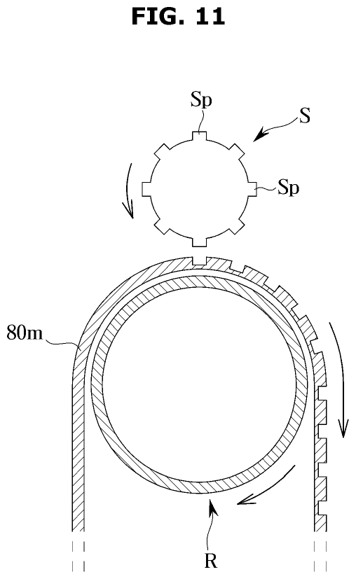

In order to improve this, the anti-glare layer 84 according to an embodiment of the present disclosure may have a structure including a uneven pattern 84a formed on one surface of a light-transmitting resin. For example, the anti-glare layer 84 may be formed through a process of forming the uneven pattern 84a for scattering light on one surface (e.g., a front surface) of the light-transmitting resin. For example, the uneven pattern 84a of the anti-glare layer 84 may be formed by a nanoimprint process using a stamp S for nanoimprint (see FIG. 11). The uneven pattern 84a may be formed after the light-transmitting resin is applied to one surface (e.g., the front surface) of the film base layer 83, or alternatively, the completed anti-glare layer 84 may be disposed on the film base layer 83 after the uneven pattern 84a is formed on one surface of the light-transmitting resin.

As such, as the anti-glare layer 84 is formed by the nanoimprint process, the thickness uniformity of the optical film 80 may be improved and the deviation of the anti-glare layer 84 between display modules 10 may be reduced. In addition, the ease of manufacturing and manufacturing yield of the optical film 80 may be improved, and the manufacturing cost may be reduced.

The low-reflection layer 85 may be disposed on one side of the anti-glare layer 84. The low-reflection layer 85 may be disposed on one side of the anti-glare layer 84 opposite to the film base layer 83. The low-reflection layer 85 may be disposed on a front surface of the anti-glare layer 84.

As an example, the low-reflection layer 85 may have a thin film shape.

The low-reflection layer 85 may be configured to reduce reflectance of incident light. In this end, for example, the low-reflection layer 85 may be configured to scatter light.

According to an embodiment, the low-reflection layer 85 may include a plurality of glass beads 85a. The low-reflection layer 85 may be formed by dispersing the plurality of glass beads 85a. For example, each of the glass beads 85a may have a low refractive index and a hollow bead shape. According to the embodiment illustrated in FIG. 5, a size of each of the glass beads 85a included in the low-reflection layer 85 may be smaller than a size of each of the glass beads 84b included in the anti-glare layer 84.

However, the composition and manufacturing method of the low-reflection layer 85 are not limited thereto, and for example, the low-reflection layer 85 may be formed by various methods, such as coating or sputtering to have the uneven pattern on one surface of the anti-glare layer 84, or forming the uneven pattern on one surface of the light-transmitting resin by the nanoimprint stamp similar to the method of manufacturing the anti-glare layer 84.

As an example, a refractive index of the low-reflection layer 85 may be lower than a refractive index of the anti-glare layer 84.

According to an embodiment, the optical film 80 may further include a surface protection layer 86. The surface protection layer 86 may form the front surface of the display module 10. The surface protection layer 86 may form a front surface of the optical film 80. The surface protection layer 86 may be configured to protect the optical film 80 and other components of the display module 10 including the optical film 80.

For example, the surface protection layer 86 may cover the low-reflection layer 85. The surface protection layer 86 may cover one side of the low-reflection layer 85 opposite to the anti-glare layer 84. The surface protection layer 86 may cover the front surface of the low-reflection layer 85. The surface protection layer 86 may be attached to the front surface of the low-reflection layer 85.

As an example, the surface protection layer 86 may have a thin film shape.

According to an embodiment, the optical film 80 may be attached to the front surface 71 of the barrier layer 70. The optical film 80 may include a light-transmitting adhesive layer 82 configured such that the optical film 80 is adhered to the barrier layer 70. The optical film 80 may be adhered to the barrier layer 70 by the light-transmitting adhesive layer 82 provided on one side of the optical film 80.

The light-transmitting adhesive layer 82 may be provided on a back surface of the optical film 80. For example, the light-transmitting adhesive layer 82 may be provided on the back surface of the film base layer 83. The light-transmitting adhesive layer 82 may be disposed on a rear side opposite to the anti-glare layer 84 of the film base layer 83. When the optical film 80 is attached to the barrier layer 70, the light-transmitting adhesive layer 82 may be disposed between the barrier layer 70 and the film base layer 83.

For example, the light-transmitting adhesive layer 82 may composed of an optical adhesive material (OCA) allowing light to transmit by including materials such as acrylic, silicone, and urethane.

According to an embodiment, the optical film 80 may further include a release film 81. The release film 81 may be configured to maintain an adhesive strength of the light-transmitting adhesive layer 82 by covering the light-transmitting adhesive layer 82 from the rear. The release film 81 may be configured to be separable from other components of the optical film 80, including the light-transmitting adhesive layer 82. Accordingly, the optical film 80 may be adhered to the barrier layer 70 by the light-transmitting adhesive layer 82 in a state in which the release film 81 is separated.

By this structure, the optical film 80 may be manufactured separately from the barrier layer 70, and may also be attached to the front surface 71 of the barrier layer 70.

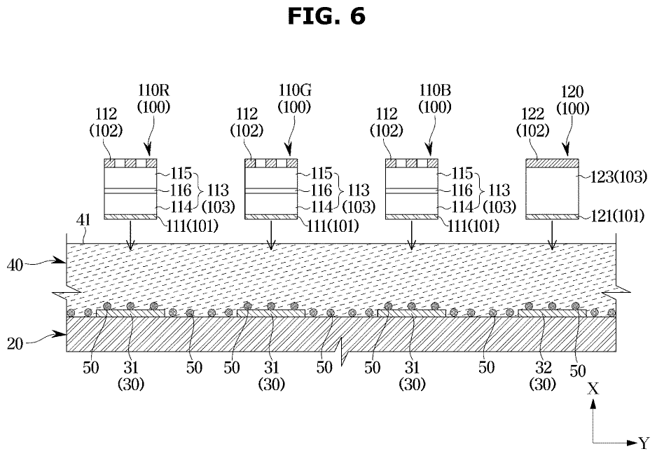

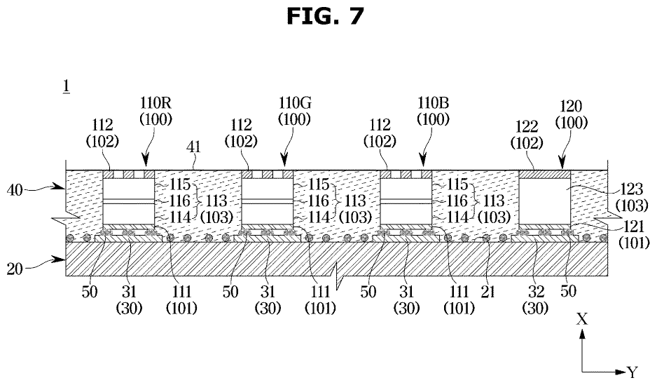

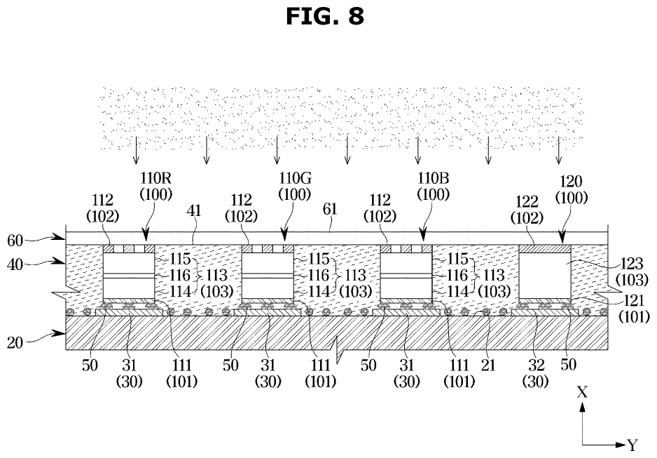

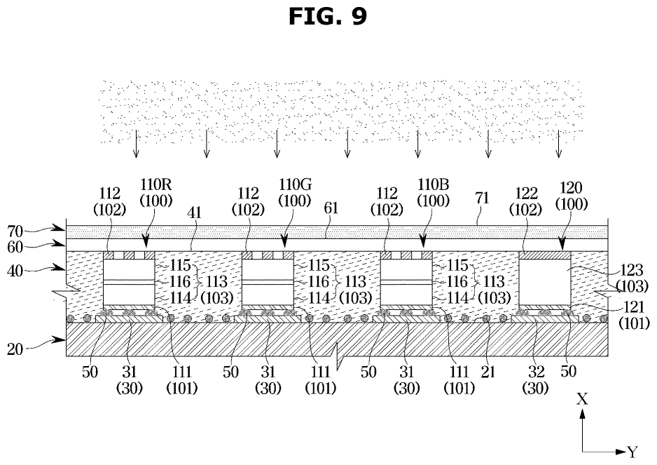

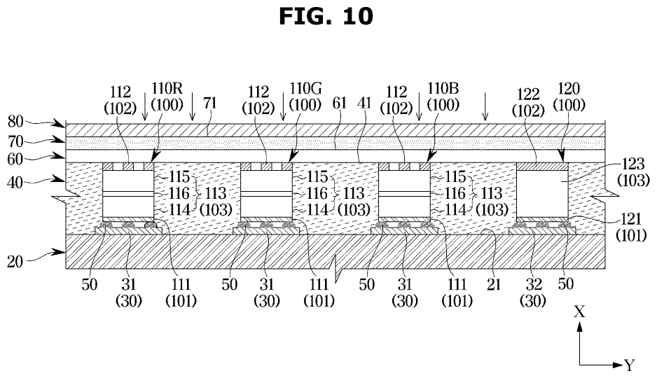

FIG. 6 is a view illustrating mounting and connecting a semiconductor element to a substrate, which is comprised in a method of manufacturing the display apparatus according to an embodiment of the present disclosure. FIG. 7 is a view illustrating a state after the semiconductor element is mounted and connected to the substrate, which is comprised in the method of manufacturing the display apparatus according to an embodiment of the present disclosure. FIG. 8 is a view illustrating forming of a light-transmitting electrode layer, which is comprised in the method of manufacturing the display apparatus according to an embodiment of the present disclosure. FIG. 9 is a view illustrating forming of a barrier layer, which is comprised in the method of manufacturing the display apparatus according to an embodiment of the present disclosure. FIG. 10 is a view illustrating attaching the optical film to the barrier layer, which is comprised in the method of manufacturing the display apparatus according to an embodiment of the present disclosure.

A method of manufacturing the display apparatus 1 according to an embodiment of the present disclosure will be described in detail below with reference to FIGS. 6 to 10.

Referring to FIG. 6, the adhesive film 40 may be disposed on the front surface 21 of the substrate 20 in order to mount the plurality of semiconductor elements 100 on the substrate 20 and electrically connect the plurality of semiconductor elements 100 to the circuit lines. For example, the adhesive film 40 may be laminated and attached to the front surface 21 of the substrate 20. As an example, the conductive layer 50 may be disposed on the inside of the adhesive film 40.

Referring to FIGS. 6 and 7, the plurality of semiconductor elements 100 including the inorganic light-emitting element 110 and the connector element 120 may be mounted on the front surface 21 of the substrate 20 and may be connected to the substrate electrode 30. According to an embodiment, the plurality of semiconductor elements 100 may be mounted on the substrate 20 through the adhesive film 40 and connected to the substrate electrode 30.

As an example, mounting the plurality of semiconductor elements 100 on the substrate 20 may be performed by bonding the substrate 20 on a wafer to which the plurality of semiconductor elements 100 is transferred.

As an example, mounting the plurality of semiconductor elements 100 on the substrate 20 may be performed by picking up the plurality of semiconductor elements 100 on the wafer using the stamp and then dropping the plurality of semiconductor elements 100 on the substrate 20.

When the semiconductor elements 100 are mounted on the substrate 20, as illustrated in FIG. 7, the conductive balls located on the substrate electrodes 30 among the conductive layers 50 may be pressed by the semiconductor elements 100, and accordingly, the insulating films of the conductive balls are broken, so that the first electrodes of the semiconductor elements 100 (e.g., the first electrode 111 of the inorganic light-emitting element 110 and the first electrode 121 of the connector element 120) and the substrate electrodes 30 (e.g., the positive pole 31 and the negative pole 32) may be connected.

The semiconductor elements 100 are mounted on the substrate 20 through the adhesive film 40, and the adhesive film 40 may be cured by heat.

However, unlike those illustrated in FIGS. 6 and 7, the plurality of semiconductor elements 100 may be mounted on the substrate 20 by various methods, such as soldering, bonding using a nanocarbon connecting material, or bonding using an elastic protrusion structure, and may be electrically connected to the substrate electrode 30.

Referring to FIG. 8, the light-transmitting electrode layer 60 may be formed after the plurality of semiconductor elements 100 is mounted on the substrate 20. For example, as illustrated in FIG. 8, the light-transmitting electrode layer 60 may be formed through the deposition process. However, unlike this, the light-transmitting electrode layer 60 may also be formed by a method such as coating. The light-transmitting electrode layer 60 may be formed in front of the plurality of semiconductor elements 100, and thus the second electrodes 112 of the plurality of inorganic light-emitting elements 110 and the second electrode 122 of the connector element 120 may be electrically connected to each other.

Referring to FIG. 9, after the light-transmitting electrode layer 60 is formed, the barrier layer 70 may be formed on the front surface 61 of the light-transmitting electrode layer 60. For example, the barrier layer 70 may be formed by depositing the light-transmitting material to cover the light-transmitting electrode layer 60. For example, the light-transmitting material of the barrier layer 70 may include various materials such as silicon dioxide (SiO₂). The material, refractive index, thickness, etc., of the barrier layer 70 may be appropriately determined in consideration of the refractive index, thickness, etc., of the light-transmitting electrode layer 60.

Referring to FIG. 10, after the barrier layer 70 is deposited on the light-transmitting electrode layer 60, the optical film 80 may be attached to the front surface 71 of the barrier layer 70. For example, the optical film 80 may be attached to the barrier layer 70 by the light-transmitting adhesive layer 82. For example, the optical film 80 may be attached to the barrier layer 70 in the state in which the release film 81 removed.

Through these steps, the display apparatus 1 according to an embodiment may be manufactured. However, the method of manufacturing the display apparatus 1 is not limited thereto and may include various steps in various embodiments.

FIG. 11 is a view illustrating a method of manufacturing the optical film included in the display apparatus according to an embodiment of the present disclosure.

Referring to FIG. 11, the method of manufacturing the optical film 80 included in the display apparatus 1 according to an embodiment of the present disclosure may include performing the nanoimprint process. In detail, the anti-glare layer 84 of the optical film 80 may be formed by the nanoimprint process forming the uneven pattern 84a using the stamp S for nanoimprint.

Forming the anti-glare layer 84 may include forming the uneven pattern 84a by pressing one side of a film base material 80m including a light-transmitting resin with the stamp S for nanoimprint. For example, the stamp S for nanoimprint may have a pattern portion Sp having a convexo-concave shape on an outer surface thereof, and as the stamp S for nanoimprint presses the film base material 80m, the uneven pattern 84a having a shape corresponding to the shape of the pattern portion Sp may be formed on one surface of the film base material 80m.

As an example, in order to further improve manufacturing efficiency of the anti-glare layer 84, manufacturing of the anti-glare layer 84 may be formed by the nanoimprint process using a roll-to-roll method. The uneven pattern 84a of the anti-glare layer 84 may be formed by seating the film base material 80m on a roller R, rotating the roller R and the stamp S for nanoimprint, and pressing the film base material 80m disposed therebetween using the roller R and the stamp S for nanoimprint.

In various embodiments, the anti-glare layer 84 may be manufactured using the deposition process such as sputtering, a slit coating process of applying a coating material through a slit, etc. However, when the anti-glare layer 84 is formed using the nanoimprint process as in the embodiment of the present disclosure, the thickness uniformity of the optical film 80 may be further improved, and the deviation between the display modules 10 may be further reduced.

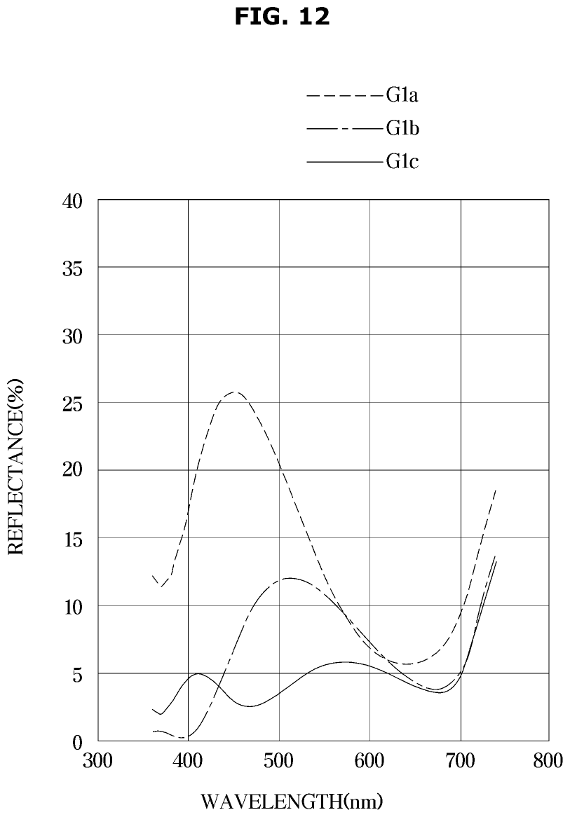

FIG. 12 is a graph showing a reflectance depending on a wavelength of incident light incident toward the barrier layer and the light-transmitting electrode layer according to a composition of the barrier layer in various embodiments.

In the graph illustrated in FIG. 12, a horizontal axis represents wavelengths of incident light, and a vertical axis represents reflectances of light.

In the graph illustrated in FIG. 12, a dotted line graph G1a shows reflectances depending on wavelengths when light is incident on the light-transmitting electrode layer 60 (material: indium tin oxide (ITO)) with a thickness of about 200 nm. In the graph illustrated in FIG. 12, a dashed-dotted line graph G1b shows reflectances depending on wavelengths when the barrier layer 70 is formed by depositing silicon dioxide (SiO₂) to a thickness of about 70 nm on the front surface of the light-transmitting electrode layer 60 (material: indium tin oxide (ITO)) with the thickness of about 200 nm, and light is incident from the front toward the barrier layer 70 and the light-transmitting electrode layer 60. In the graph illustrated in FIG. 12, a solid line graph G1c shows reflectances depending on wavelengths when the barrier layer 70 is formed by depositing silicon dioxide (SiO₂) to a thickness of about 90 nm on the front surface of the light-transmitting electrode layer 60 (material: indium tin oxide (ITO)) with the thickness of about 200 nm, and light is incident from the front toward the barrier layer 70 and the light-transmitting electrode layer 60.

As may be seen from FIG. 12, when silicon dioxide (SiO₂) is deposited on the light-transmitting electrode layer 60 to form the barrier layer 70, the thin film interference phenomenon may be improved and the reflectance may be significantly reduced. It may be seen that this improvement effect will be greater as the thickness of the barrier layer 70 becomes thicker (see the dashed-dotted line graph G1b and solid-line graph G1c).

In particular, it may be seen that compared to an example in which only the light-transmitting electrode layer 60 is included, the average reflectance is reduced by about 64 percent in an example in which the barrier layer 70 is formed by depositing silicon dioxide (SiO₂) to the thickness of about 90 nm on the light-transmitting electrode layer 60.

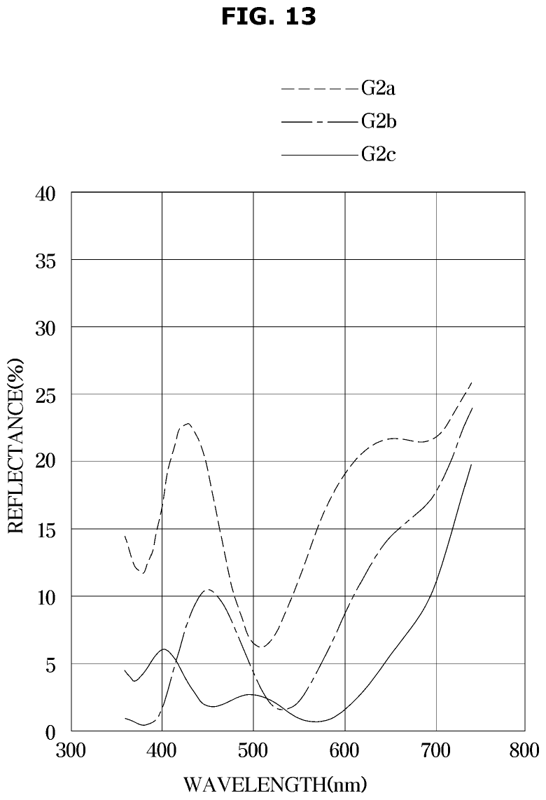

FIG. 13 is a graph showing a reflectance depending on a wavelength of incident light incident toward the barrier layer and the light-transmitting electrode layer according to a composition of the barrier layer in various embodiments.

In the graph illustrated in FIG. 13, a horizontal axis represents wavelengths of incident light, and a vertical axis represents reflectances of light.

In the graph illustrated in FIG. 13, a dotted line graph G2a shows reflectances depending on wavelengths when light is incident on the light-transmitting electrode layer 60 (material: indium tin oxide (ITO)) with a thickness of about 300 nm. In the graph illustrated in FIG. 13, a dashed-dotted line graph G2b shows reflectances depending on wavelengths when the barrier layer 70 is formed by depositing silicon dioxide (SiO₂) to the thickness of about 70 nm on the front surface of the light-transmitting electrode layer 60 (material: indium tin oxide (ITO)) with the thickness of about 300 nm, and light is incident from the front toward the barrier layer 70 and the light-transmitting electrode layer 60. In the graph illustrated in FIG. 13, a solid line graph G2c shows reflectances depending on wavelengths when the barrier layer 70 is formed by depositing silicon dioxide (SiO₂) to the thickness of about 90 nm on the front surface of the light-transmitting electrode layer 60 (material: indium tin oxide (ITO)) with the thickness of about 300 nm, and light is incident from the front toward the barrier layer 70 and the light-transmitting electrode layer 60.

As may be seen from FIG. 13, when silicon dioxide (SiO₂) is deposited on the light-transmitting electrode layer 60 to form the barrier layer 70, the thin film interference phenomenon may be improved and the reflectance may be significantly reduced. It may be seen that this improvement effect will be greater as the thickness of the barrier layer 70 becomes thicker (see the dashed-dotted line graph G2b and solid-line graph G2c).

In particular, it may be seen that compared to an example in which only the light-transmitting electrode layer 60 is included, the average reflectance is reduced by about 70 percent in an example in which the barrier layer 70 is formed by depositing silicon dioxide (SiO₂) to the thickness of about 90 nm on the light-transmitting electrode layer 60.

FIG. 14 is an enlarged cross-sectional view illustrating some components of the display apparatus according to an embodiment of the present disclosure.

Referring to FIG. 14, the display module 10 included in the display apparatus 1 according to an embodiment of the present disclosure may include the barrier layer 70 including a front portion 70a and a side portion 70b. The front portion 70a and the side portion 70b of the barrier layer 70 may extend in different directions.

The barrier layer 70 may cover the front surface 61 of the light-transmitting electrode layer 60. The front portion 70a of the barrier layer 70 may cover the front surface 61 of the light-transmitting electrode layer 60. The front portion 70a of the barrier layer 70 may extend in a direction substantially parallel to the light-transmitting electrode layer 60 (e.g., in the direction parallel to the Y-Z plane). The front portion 70a of the barrier layer 70 may extend in a direction substantially parallel to the mounting surface 21 of the substrate 20 (e.g., in the direction parallel to the Y-Z plane).

For example, the front portion 70a of the barrier layer 70 may be formed by depositing the light-transmitting material such as silicon dioxide (SiO₂) on the front surface 61 of the light-transmitting electrode layer 60.

The barrier layer 70 may cover a side surface 62 of the light-transmitting electrode layer 60. The side surface 62 of the light-transmitting electrode layer 60 may be defined as a side surface provided at the outermost end of the light-transmitting electrode layer 60 in a direction in which the mounting surface 21 extends. The side surface 62 of the light-transmitting electrode layer 60 may be defined as an edge surface of the light-transmitting electrode layer 60. The side portion 70b of the barrier layer 70 may cover the side surface 62 of the light-transmitting electrode layer 60. The barrier layer 70 may extend in a direction in which the side surface 62 of the light-transmitting electrode layer 60 extends (e.g., in the X direction). The barrier layer 70 may extend in a thickness direction of the light-transmitting electrode layer 60 (e.g., in the X direction).

For example, the side portion 70b of the barrier layer 70 may be formed by depositing the light-transmitting material such as silicon dioxide (SiO₂) on the side surface 62 of the light-transmitting electrode layer 60.

The barrier layer 70 may cover a side surface 22 of the substrate 20. The side surface 22 of the substrate 20 may be defined as a side surface provided at the outermost end of the substrate 20 in the direction in which the mounting surface 21 extends. The side surface 22 of the substrate 20 may be defined as an edge surface of the substrate 20. The side portion 70b of the barrier layer 70 may cover the side surface 22 of the substrate 20. The barrier layer 70 may extend in a direction in which the side surface 22 of the substrate 20 extends (e.g., in the X direction). The barrier layer 70 may extend in a thickness direction of the substrate 20 (e.g., in the X direction).

For example, the side portion 70b of the barrier layer 70 may be formed by depositing the light-transmitting material such as silicon dioxide (SiO₂) on the side surface 22 of the substrate 20.

The barrier layer 70 may cover a side surface 42 of a light-emitting portion. In an embodiment in which the display module 10 includes the adhesive film 40, the barrier layer 70 may cover the side surface 42 of the adhesive film 40. The side surface 42 of the adhesive film 40 may be defined as a side surface provided at the outermost end of the adhesive film 40 in the direction in which the mounting surface 21 extends. The side surface 42 of the adhesive film 40 may be defined as an edge surface of the adhesive film 40. The side portion 70b of the barrier layer 70 may cover the side surface 42 of the adhesive film 40. The barrier layer 70 may extend in a direction in which the side surface 42 of the adhesive film 40 extends (e.g., in the X direction). The barrier layer 70 may extend in a thickness direction of the adhesive film 40 (e.g., in the X direction).

For example, the side portion 70b of the barrier layer 70 may be formed by depositing the light-transmitting material such as silicon dioxide (SiO₂) on the side surface 42 of the adhesive film 40.

The side portion 70b of the barrier layer 70 may extend from the side surface 62 of the light-transmitting electrode layer 60 to the side surface 22 of the substrate 20. The side portion 70b of the barrier layer 70 is formed integrally, may cover the side surface 62 of the light-transmitting electrode layer 60, the side surface 42 of the adhesive film 40, and the side surface 22 of the substrate 20, respectively, by extending from the side surface 62 of the light-transmitting electrode layer 60 to the side surface 22 of the substrate 20, and may seal a gap between the respective layers. The side portion 70b of the barrier layer 70 may be formed through a process of depositing the light-transmitting material from the side surface 62 of the light-transmitting electrode layer 60 to the side surface 22 of the substrate 20 to cover an area between the side surface 62 of the light-transmitting electrode layer 60 and the side surface 22 of the substrate 20.

The front portion 70a and the side portion 70b of the barrier layer 70 may be connected to each other. For example, the front portion 70a and the side portion 70b of the barrier layer 70 may be formed integrally. For example, the front portion 70a and the side portion 70b of the barrier layer 70 may be formed integrally through the deposition process.

By the structure of the barrier layer 70 as in the embodiment described with reference to FIG. 14, external moisture or foreign substances may be more effectively prevented from penetrating into the inside of each layer of the display module 10.

As with the embodiments described with reference to FIGS. 1 to 11, the display module 10 according to the embodiment of FIG. 14 may include the optical film 80, and the optical film 80 may cover only the front portion 70a of the barrier layer 70 or may cover both the front portion 70a and the side portion 70b of the barrier layer 70.

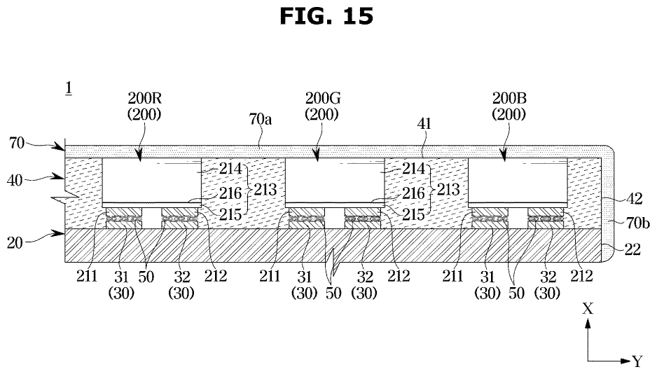

FIG. 15 is an enlarged cross-sectional view illustrating some components of the display apparatus according to an embodiment of the present disclosure.

In describing an embodiment of the present disclosure with reference to FIG. 15, the same drawing reference numerals may be given to components corresponding to those of the embodiments described with reference to FIGS. 1 to 14, and the same description may not be repeated.

Referring to FIG. 15, the display apparatus 1 according to may embodiment of the present disclosure may include a semiconductor element 200 of a flip-chip type. For example, the flip-chip type semiconductor element 200 may be an inorganic light-emitting element.

The semiconductor element 200 may be mounted on the substrate 20. The semiconductor element 200 may be mounted on the front surface 21 of the substrate 20. The semiconductor element 200 may be electrically connected to the circuit line of the substrate 20 by being connected to the substrate electrode 30.

The semiconductor element 200 may be provided in plurality. For example, the semiconductor elements 200 may include a red inorganic light-emitting element 200R, a green inorganic light-emitting element 200G, and a blue inorganic light-emitting element 200B.

Each of the semiconductor elements 200 may include the first electrode 211 connected to the substrate electrode 30, a second electrode 212, and a semiconductor layer 213 through which current flows based on a predetermined voltage being applied between the first electrode 211 and the second electrode 212.

The first electrode 211 and the second electrode 212 may each be disposed on one surface of the semiconductor layer 213 adjacent to the mounting surface 21. The first electrode 211 and the second electrode 212 may each be disposed on a back surface of the semiconductor layer 213. The first electrode 211 and the second electrode 212 may each be connected to the substrate electrode 30 by being disposed on the back surface of the semiconductor layer 213. For example, the first electrode 211 and the second electrode 212 may each be connected to the substrate electrode 30 by the conductive layer 50 (e.g., including the plurality of conductive balls). For example, the first electrode 211 may be connected to the positive pole 31 of the substrate electrode 30, and the second electrode 212 may be connected to the negative pole 32 of the substrate electrode 30.

According to an embodiment, the semiconductor layer 213 may include a first semiconductor layer 214, a second semiconductor layer 215, and an active layer 216 disposed between the first semiconductor layer 214 and the second semiconductor layer 215. The first semiconductor layer 214, the active layer 216, and the second semiconductor layer 215 may be arranged in the direction perpendicular to the substrate 20. For example, the first semiconductor layer 214, the active layer 216, and the second semiconductor layer 215 may be arranged in the front-rear direction X, which is a direction in which light is emitted. For example, the active layer 216 may be disposed in front of the first semiconductor layer 214, and the second semiconductor layer 215 may be disposed in rear of the active layer 216. In this case, the first electrode 211 and the second electrode 212 may be disposed on a back surface of the second semiconductor layer 215.

The first semiconductor layer 214 and the second semiconductor layer 215 may each be one of a P-type semiconductor layer and an N-type semiconductor layer.

The active layer 216 may be disposed between the first semiconductor layer 214 and the second semiconductor layer 215 and configured to emit light by combining electrons and holes when the predetermined voltage is applied between the first electrode 211 and the second electrode 212 of the semiconductor layer 213. For example, the active layer 216 may be configured as a quantum well (such as a multiple-quantum-well (MQW) or a single-quantum-well (SQW)).

According to an embodiment, the display module 10 may include the adhesive film 40, and the semiconductor elements 200 may be fixed to the substrate 20 by the adhesive film 40.

The adhesive film 40 and a plurality of the semiconductor elements 200 may have the same or nearly similar thicknesses in the front-rear direction X. That is, in the display module 10, the plurality of the semiconductor elements 200 and the adhesive film 40 may form one layer, and the layer including the plurality of semiconductor elements 200 and the adhesive film 40 may be referred to as a ‘light-emitting layer’.

In a case in which the semiconductor element 200 is of the flip-chip type as in the present embodiment, as both the electrodes 211 and 212 of the semiconductor element 200 are electrically connected to the substrate 20, a component such as the light-transmitting electrode layer 60 described in the above embodiment may not be included.

According to an embodiment of the present disclosure, the display module 10 may include the barrier layer 70 including the front portion 70a and the side portion 70b. The front portion 70a and the side portion 70b of the barrier layer 70 may extend in different directions.

The barrier layer 70 may cover the front surface 41 of the light-emitting layer. The barrier layer 70 may cover the semiconductor element 200 and the front surface 41 of the adhesive film 40. The front portion 70a of the barrier layer 70 may extend in a direction substantially parallel to the light-emitting layer (e.g., in the direction parallel to the Y-Z plane). The front portion 70a of the barrier layer 70 may extend in the direction substantially parallel to the mounting surface 21 of the substrate 20 (e.g., in the direction parallel to the Y-Z plane).

For example, the front portion 70a of the barrier layer 70 may be formed by depositing the light-transmitting material such as silicon dioxide (SiO₂) on the plurality of semiconductor elements 200 and the front surface 41 of the light-emitting layer including the adhesive film 40.

The barrier layer 70 may cover the side surface 42 of the light-emitting portion. In an embodiment in which the display module 10 includes the adhesive film 40, the barrier layer 70 may cover the side surface 42 of the adhesive film 40. The side surface 42 of the adhesive film 40 may be defined as a side surface provided at the outermost end of the adhesive film 40 in the direction in which the mounting surface 21 extends. The side surface 42 of the adhesive film 40 may be defined as an edge surface of the adhesive film 40. The side portion 70b of the barrier layer 70 may cover the side surface 42 of the adhesive film 40. The barrier layer 70 may extend in the direction in which the side surface 42 of the adhesive film 40 extends (e.g., in the X direction). The barrier layer 70 may extend in the thickness direction of the adhesive film 40 (e.g., in the X direction).

For example, the side portion 70b of the barrier layer 70 may be formed by depositing the light-transmitting material such as silicon dioxide (SiO₂) on the side surface 42 of the adhesive film 40.

The barrier layer 70 may cover the side surface 22 of the substrate 20. The side surface 22 of the substrate 20 may be defined as a side surface provided at the outermost end of the substrate 20 in the direction in which the mounting surface 21 extends. The side surface 22 of the substrate 20 may be defined as an edge surface of the substrate 20. The side portion 70b of the barrier layer 70 may cover the side surface 22 of the substrate 20. The barrier layer 70 may extend in the direction in which the side surface 22 of the substrate 20 extends (e.g., in the X direction). The barrier layer 70 may extend in the thickness direction of the substrate 20 (e.g., in the X direction).

For example, the side portion 70b of the barrier layer 70 may be formed by depositing the light-transmitting material such as silicon dioxide (SiO₂) on the side surface 22 of the substrate 20.

The side portion 70b of the barrier layer 70 may extend from the side surface 42 of the adhesive film 40 to the side surface 22 of the substrate 20. The side portion 70b of the barrier layer 70 is formed integrally, may cover the side surface 42 of the adhesive film 40 and the side surface 22 of the substrate 20, respectively, by extending from the side surface 42 of the adhesive film 40 to the side surface 22 of the substrate 20, and may seal the gap between the respective layers. The side portion 70b of the barrier layer 70 may be formed through a process of depositing the light-transmitting material from the side surface 42 of the adhesive film 40 to the side surface 22 of the substrate 20 to cover the area between the side surface 62 of the adhesive film 40 and the side surface 22 of the substrate 20.

The front portion 70a and the side portion 70b of the barrier layer 70 may be connected to each other. For example, the front portion 70a and the side portion 70b of the barrier layer 70 may be formed integrally. For example, the front portion 70a and the side portion 70b of the barrier layer 70 may be formed integrally through the deposition process.

By the structure of the barrier layer 70 as in the embodiment described with reference to FIG. 15, external moisture or foreign substances may be more effectively prevented from penetrating into the inside of each layer of the display module 10.

As with the embodiments described with reference to FIGS. 1 to 11, the display module 10 according to the embodiment of FIG. 15 may include the optical film 80, and the optical film 80 may cover only the front portion 70a of the barrier layer 70 or may cover both the front portion 70a and the side portion 70b of the barrier layer 70.

A method of manufacturing a display apparatus according to an embodiment of the present disclosure may include mounting a plurality of inorganic light-emitting elements including a first electrode, a second electrode, and a semiconductor layer configured to emit light based on a voltage being applied between the first electrode and the second electrode, on a mounting surface of a substrate, such that the first electrode faces the mounting surface, forming a light-transmitting electrode layer, which is configured to electrically connect the second electrode of each of the plurality of inorganic light-emitting elements, on one side of the plurality of inorganic light-emitting elements opposite to the mounting surface, forming a barrier layer configured to cover the light-transmitting electrode layer by depositing a light-transmitting material on one side of the light-transmitting electrode layer opposite to the plurality of inorganic light-emitting elements, and covering the barrier layer by attaching an optical film to one side of the barrier layer opposite to the light-transmitting electrode layer.

The attaching of the optical film to the barrier layer may include attaching the optical film to the barrier layer with a light-transmitting adhesive layer provided on one side of the optical film.

The light-transmitting material may include at least one of silicon dioxide (SiO₂), silicon nitride (SiNx), and aluminum oxide (Al₂O₃).

The method of manufacturing a display apparatus may further include forming the optical film. The forming of the optical film may include forming an anti-glare layer configured to scatter light on one surface of a film base layer configured to allow light to transmit, and disposing a low-reflection layer on one side of the anti-glare layer opposite to the film base layer.

The forming of the anti-glare layer may include forming a uneven pattern for scattering light on one surface of a light-transmitting resin opposite to the film base layer using a stamp for nanoimprint, or dispersing a plurality of glass beads.

The low-reflection layer may be formed by dispersing a plurality of glass beads.

The forming of the optical film may further include forming a light-transmitting adhesive layer, which is configured to adhere the film base layer to the barrier layer, on the other surface of the film base layer.

The substrate may include a side surface provided at the outermost end of the substrate in one direction in which the mounting surface extends. The light-transmitting electrode layer may include a side surface provided at the outermost end of the light-transmitting electrode layer in the one direction. The forming of the barrier layer may include further depositing the light-transmitting material from the side surface of the light-transmitting electrode layer to the side surface of the substrate so that the barrier layer covers an area between the side surface of the light-transmitting electrode layer and the side surface of the substrate.

The method of manufacturing the display apparatus may further include disposing an adhesive film configured to fix the plurality of inorganic light-emitting elements to the mounting surface on the mounting surface. The forming of the barrier layer may further include further depositing the light-transmitting material on a side surface of the adhesive film so that the barrier layer covers the side surface of the adhesive film provided at the outermost end of the adhesive film in the one direction.

A display module according to an embodiment of the present disclosure may include a substrate including circuit lines, a plurality of inorganic light-emitting elements mounted on the substrate, the plurality of inorganic light-emitting elements including a first electrode connected to the circuit line, a second electrode opposite to the first electrode, and a semiconductor layer configured to emit light based on a voltage being applied between the first electrode and the second electrode, a light-transmitting electrode layer configured to cover the plurality of inorganic light-emitting elements and to be electrically connected to the second electrode of each of the plurality of inorganic light-emitting elements, a barrier layer configured to cover the light-transmitting electrode layer by being deposited on one side of the light-transmitting electrode layer opposite to the plurality of inorganic light-emitting elements, and an optical film configured to cover the barrier layer by being attached to one side of the barrier layer opposite to the light-transmitting electrode layer.

The barrier layer may be configured to seal the light-transmitting electrode layer and the plurality of inorganic light-emitting elements from the outside on the optical film side.

The barrier layer may be configured such that light transmitted through the barrier layer and incident on the light-transmitting electrode layer is reflected by the light-transmitting electrode layer at a degree less than a predetermined reflectance.

The barrier layer may include at least one of silicon dioxide (SiO₂), silicon nitride (SiNx), and aluminum oxide (Al₂O₃).

The optical film may include a film base layer configured to allow light to transmit, an anti-glare layer disposed on one side of the film base layer opposite to the barrier layer, and a low-reflection layer disposed on one side of the anti-glare layer opposite to the film base layer.

The anti-glare layer may include a uneven pattern formed on one surface of a light-transmitting resin.

The optical film may further include a light-transmitting adhesive layer disposed between the barrier layer and the film base layer and configured to adhere the film base layer to the barrier layer.

The optical film may further include a surface protection layer configured to cover one side of the low-reflection layer opposite to the anti-glare layer.

The substrate may include a side surface provided at the outermost end of the substrate in a first direction in which a surface on which the plurality of inorganic light-emitting elements is mounted on the substrate extends. The light-transmitting electrode layer may include a side surface provided at the outermost end of the light-transmitting electrode layer in the first direction. The barrier layer may include a front portion extending in the first direction to cover one surface of the light-transmitting electrode layer opposite to the plurality of inorganic light-emitting elements, and a side portion extending in a second direction different from the first direction from the side surface of the light-transmitting electrode layer to the side surface of the substrate.

The display module may further include an adhesive film configured to fix the plurality of inorganic light-emitting elements to the substrate. The side portion may cover a side surface of the adhesive film provided at the outermost end of the adhesive film in the first direction.

A display apparatus according to an embodiment of the present disclosure may include a plurality of display modules arranged in a matrix form of M*N. Each of the plurality of display modules may include a substrate including circuit lines, a light-emitting layer including a plurality of inorganic light-emitting elements including a semiconductor layer configured to emit light based on a voltage being applied between electrodes connected to the circuit lines and an adhesive film configured to mount the plurality of inorganic light-emitting elements on the substrate, a barrier layer configured to cover the light-emitting layer by being deposited on one side of the light-emitting layer opposite to the substrate, and an optical film configured to cover the barrier layer by being attached to one side of the barrier layer opposite to the light-emitting layer.

According to the present disclosure, because a display module includes a barrier layer covering layers of the display module, such as a light-emitting layer and a light-transmitting electrode layer, moisture, foreign substances, etc. can be prevented from entering between the layers, and the display module can be efficiently protected.

According to the present disclosure, because the barrier layer covers some layers of the display module from front and sides, moisture, foreign substances, etc. can be more effectively prevented from entering between the layers.

According to the present disclosure, because the barrier layer is formed by being deposited on the light-transmitting electrode layer, the thickness uniformity of the barrier layer can be improved, and thus a deviation between the display modules can be reduced, so that the manufacturing yield can be improved and the manufacturing cost can be reduced.

According to the present disclosure, because some components of an optical film, for example, a uneven pattern of the anti-glare layer, is formed through a nanoimprint process, the thickness uniformity of an anti-glare layer can be improved, and thus the deviation between the display modules can be reduced, so that the manufacturing yield can be improved and the manufacturing cost can be reduced.

According to the present disclosure, because the barrier layer is composed of silicon dioxide or the like to have a predetermined refractive index, thin film interference caused by light incident toward a transparent electrode layer can be reduced.

Effects according to the present disclosure are not limited to the effects mentioned above, and other effects not mentioned will be clearly understood by those skilled in the art to which the present disclosure belongs from the fallowing description.

The foregoing has illustrated and described specific embodiments. However, it should be understood by those of skilled in the art that the present disclosure is not limited to the above-described embodiments, and various changes and modifications may be made without departing from the technical idea of the present disclosure described in the following claims and their equivalents.

1. A method of manufacturing a display apparatus, comprising:
mounting a plurality of inorganic light-emitting elements that respectively include a first electrode, a second electrode, and a semiconductor layer that is configured to emit light based on a voltage being applied between the first electrode and the second electrode, on a mounting surface of a substrate, such that the first electrode faces the mounting surface;
forming a light-transmitting electrode layer, which is configured to electrically connect the second electrode of the plurality of inorganic light-emitting elements, respectively, on one side of the plurality of inorganic light-emitting elements opposite the mounting surface;
forming a barrier layer configured to cover the light-transmitting electrode layer by depositing a light-transmitting material on one side of the light-transmitting electrode layer opposite the plurality of inorganic light-emitting elements; and
covering the barrier layer by attaching an optical film to one side of the barrier layer opposite the light-transmitting electrode layer.

2. The method of manufacturing the display apparatus according to claim 1, wherein the attaching of the optical film to the one side of the barrier layer comprises:
attaching the optical film to the one side of the barrier layer with a light-transmitting adhesive layer on one side of the optical film.

3. The method of manufacturing the display apparatus according to claim 1, wherein
the light-transmitting material comprises at least one of silicon dioxide (SiO₂), silicon nitride (SiNx), and aluminum oxide (Al₂O₃).

4. The method of manufacturing the display apparatus according to claim 1, further comprising:
forming the optical film,
wherein the forming of the optical film comprises:
forming an anti-glare layer configured to scatter light on one surface of a film base layer configured to allow light to transmit; and
disposing a low-reflection layer on one side of the anti-glare layer opposite the film base layer.

5. The method of manufacturing the display apparatus according to claim 4, wherein
the forming of the anti-glare layer comprises: forming a uneven pattern to scatter light on one surface of a light-transmitting resin opposite the film base layer using a stamp for nanoimprint, or dispersing a plurality of glass beads.

6. The method of manufacturing the display apparatus according to claim 4, wherein
the low-reflection layer is formed by dispersing a plurality of glass beads.

7. The method of manufacturing the display apparatus according to claim 4, wherein the forming of the optical film further comprises:
forming a light-transmitting adhesive layer, which is configured to adhere the film base layer to the barrier layer, on another surface of the film base layer.

8. The method of manufacturing the display apparatus according to claim 1, wherein
the substrate comprises a side surface at an outermost end of the substrate along one direction in which the mounting surface extends,
the light-transmitting electrode layer comprises a side surface at an outermost end of the light-transmitting electrode layer along the one direction, and
the forming of the barrier layer comprises further depositing the light-transmitting material from the side surface of the light-transmitting electrode layer to the side surface of the substrate so that the barrier layer covers an area between the side surface of the light-transmitting electrode layer and the side surface of the substrate.

9. The method of manufacturing the display apparatus according to claim 8, further comprising:
disposing an adhesive film configured to fix the plurality of inorganic light-emitting elements to the mounting surface on the mounting surface,
wherein the forming of the barrier layer further comprises: further depositing the light-transmitting material on a side surface of the adhesive film so that the barrier layer covers the side surface of the adhesive film provided at the outermost end of the adhesive film along the one direction.

10. A display module comprising:
a substrate including circuit lines;
a plurality of inorganic light-emitting elements to be mounted on the substrate, the plurality of inorganic light-emitting elements respectively including a first electrode connected to a circuit line, among the circuit lines, a second electrode opposite the first electrode, and a semiconductor layer configured to emit light based on a voltage being applied between the first electrode and the second electrode;
a light-transmitting electrode layer configured to cover the plurality of inorganic light-emitting elements and to be electrically connected to the second electrode of the plurality of inorganic light-emitting elements, respectively;
a barrier layer configured to cover the light-transmitting electrode layer by being deposited on one side of the light-transmitting electrode layer opposite the plurality of inorganic light-emitting elements; and
an optical film configured to cover the barrier layer by being attached to one side of the barrier layer opposite the light-transmitting electrode layer.

11. The display module according to claim 10, wherein
the barrier layer is configured to seal the light-transmitting electrode layer and the plurality of inorganic light-emitting elements from outside on a side of the barrier layer on which the optical film covers the barrier layer.

12. The display module according to claim 10, wherein
the barrier layer is configured such that light transmitted through the barrier layer and incident on the light-transmitting electrode layer is reflected by the light-transmitting electrode layer at a degree less than a predetermined reflectance.

13. The display module according to claim 10, wherein
the barrier layer comprises at least one of silicon dioxide (SiO₂), silicon nitride (SiNx), and aluminum oxide (Al₂O₃).

14. The display module according to claim 10, wherein
the optical film comprises:
a film base layer configured to allow light to transmit;
an anti-glare layer disposed on one side of the film base layer opposite to the barrier layer; and
a low-reflection layer disposed on one side of the anti-glare layer opposite to the film base layer.

15. The display module according to claim 14, wherein
the anti-glare layer comprises a uneven pattern formed on one surface of a light-transmitting resin.
